(19) United States
(12) Patent Application Publication
(10) Pub. No.: US 2015/0041883 A1
(43) Pub. Date: Feb. 12, 2015

(54) SEMICONDUCTOR DEVICE

(71) Applicant: Hitachi, Ltd., Tokyo (JP)

(72) Inventors: Hiroki Kimura, Tokyo (JP); Youhei Yanagida, Tokyo (JP); Kenji Miyakoshi, Tokyo (JP); Tomoyuki Miyoshi, Tokyo (JP); Takayuki Ooshima, Tokyo (JP)

(73) Assignee: HITACHI, LTD.

(21) Appl. No.: 14/452,583

(22) Filed: Aug. 6, 2014

(30) Foreign Application Priority Data
Aug. 6, 2013 (JP) 2013-162946

(51) Int. Cl. H01L 27/02; H01L 29/08; H01L 29/78; H01L 29/10

(52) U.S. Cl. CPC H01L 27/0255; H01L 27/0259; H01L 29/1095; H01L 29/0865; H01L 29/7824; H01L 29/0878
USPC 257/328

(57) ABSTRACT

An object of the present invention is to improve the ESD resistance of an electrostatic protection element.

The essence of the basic idea resides in that an electrostatic protection element ESD is configured to include not a thyristor or an npn bipolar transistor, but a pnp bipolar transistor so as to be connected in parallel with a diode. In other words, the essence of the basic idea resides in that an electrostatic protection element ESD is constituted by a diode parasitically provided with a pnp bipolar transistor.

### CROSS-REFERENCE TO RELATED APPLICATION

This application claims the priority of Japanese Patent Application No. 2013-162946 filed Aug. 6, 2013, which is incorporated herein by reference in its entirety.

### BACKGROUND OF THE INVENTION

1. Field of the Invention

The present invention relates to a semiconductor device, and for example, relates to a technique effectively applied to a semiconductor device including an electrostatic protection element.

2. Background Art

JP-A-2011-124397 discloses a technique for providing a protection diode, which has high ESD (Electro Static Discharge) resistance, and can be produced by the same process as that for a high withstand voltage transistor to be protected. Specifically, a gate oxide film is formed on the surface of a substrate at a pn junction formed by an n-type low concentration semiconductor substrate constituting a cathode region and a p-type low concentration diffusion region constituting an anode region, and a gate electrode which is provided so as to straddle the gate oxide film and a field oxide film is electrically connected to an anode electrode. According to this configuration, an electric field at the pn junction is relaxed during avalanche breakdown, whereby the ESD resistance can be improved. Further, the withstand voltage can be adjusted by changing the length of the field oxide film.

JP-A-2001-320047 discloses a technique for forming a p⁺-type anode layer adjacent to an n⁺-type drain layer of an LDMOS for realizing a lateral DMOS having high ESD resistance. This anode layer generates a hole during an ESD operation. This hole flows in a base layer through an active layer, and an electron flows in a drain layer from a source layer. Due to this, a parasitic thyristor operates, and therefore, a holding voltage between the source and the drain under a high current condition can be decreased, and a current distribution can be made uniform.

JP-A-2012-64830 discloses a technique for improving the ESD resistance by preventing local current concentration at a drain end. Specifically, an n-type high concentration buried region and an n-type high concentration buried contact region are disposed. In a source electrode, an n-type high concentration region and a p-type high concentration region are arranged side by side in the channel width direction on the upper surface of a p-type well. According to this configuration, a vertical transistor is activated as well as a parasitic transistor, and therefore, a current flowing in the parasitic transistor is suppressed, and by suppressing the local current concentration at the drain end, the ESD resistance against electrostatic discharge is improved. Further, by adjusting the width of the n-type high concentration region of the source, a turn-on voltage can be adjusted.

JP-A-2006-324346 discloses a technique for improving the withstand voltage of a LOCOS offset drain-type high withstand voltage MOS transistor by relaxing an electric field at an end of a LOCOS oxide film of the LOCOS offset drain-type high withstand voltage MOS transistor and also for forming an electric field relaxing layer without adding a process. Specifically, a drain layer is formed spaced apart at a predetermined distance from an end portion of a LOCOS oxide film in an electric field relaxing layer. According to this configuration, the concentration gradient in the end portion of the LOCOS oxide film is relaxed and the electric field concentration is suppressed. As a result, the withstand voltage of the LOCOS offset drain-type high withstand voltage MOS transistor can be improved.

An electrostatic protection element is a semiconductor element which has a function that when an electrostatic noise or the like is applied to an integrated circuit, an electric charge due to the electrostatic noise is released to the outside without adversely affecting the integrated circuit. Therefore, it is the most important factor for the electrostatic protection element to be able to release a larger electric charge.

The electrostatic protection element having such a function is roughly divided into (1) an element in which a voltage drop called “snapback” occurs after operation, and (2) an element in which a voltage drop called “snapback” does not occur. In particular, the electrostatic protection element is roughly divided into the following two types: an electrostatic protection element typified by a thyristor or an npn bipolar transistor, in which a large voltage drop occurs; and an electrostatic protection element typified by a pnp bipolar transistor, in which a small voltage drop occurs, or a diode, in which a voltage drop does not occur.

In the former electrostatic protection element, because a large voltage drop occurs, it has an advantage that the ratio of the breakdown current (also sometimes referred as “ESD resistance” in this specification) to the power consumption of the electrostatic protection element defined by current x voltage can be increased. On the other hand, for example, as a circuit containing an inductance, in a circuit with a mode in which a voltage is increased above a power supply voltage by a back electromotive force of the inductance, because of a large voltage drop, a holding voltage may drop below the voltage of the back electromotive force. Due to this, the former electrostatic protection element is not used in a circuit containing an inductance such as a motor, and the latter electrostatic protection element in which a large voltage drop does not occur is used in such a circuit.

However, because a large voltage drop does not occur in the latter electrostatic protection element, the ratio of the breakdown current (ESD resistance) to the power consumption of the electrostatic protection element defined by current x voltage is lower in the latter electrostatic protection element than in the former electrostatic protection element. Due to this, in the latter electrostatic protection element, there is a room for improvement from the viewpoint of improvement of ESD resistance.

### SUMMARY OF THE INVENTION

An object of the present invention is to improve the ESD resistance of an electrostatic protection element.

The other objects and novel features will be apparent from the description of the present specification and the accompanying drawings.

A semiconductor device according to one embodiment includes an electrostatic protection element including: (a) a source region which has a p-type semiconductor region formed on an n-type semiconductor layer; (b) a drain region which has a p-type semiconductor region formed apart from the source region on the n-type semiconductor layer; (c) an n-type semiconductor region which is formed on the n-type semiconductor layer and is in contact with the source region; (d) a gate insulating film which is formed on the n-type semiconductor layer; and (e) a gate electrode which is formed on the gate insulating film. Here, the source region, the n-type semiconductor region, and the gate electrode are electrically connected to one another.

According to this embodiment, the ESD resistance of the electrostatic protection element included in the semiconductor device can be improved.

### BRIEF DESCRIPTION OF THE DRAWINGS

FIG. 1 is a circuit diagram showing an example of a circuit structure of an electrostatic protection element in a related art 1.

FIG. 2 is a graph showing a relationship between an inter-terminal voltage between terminals to which the electrostatic protection element in the related art 1 is connected and a current flowing in the electrostatic protection element.

FIG. 3 is a graph showing a relationship between an inter-terminal voltage between terminals to which the electrostatic protection element is connected and a current flowing in the electrostatic protection element when the electrostatic protection element in the related art 1 was used in a circuit containing an inductance.

FIG. 4 is a circuit diagram showing an example of a circuit structure of an electrostatic protection element in a related art 2.

FIG. 5 is a graph showing a relationship between an inter-terminal voltage between terminals to which the electrostatic protection element in the related art 2 is connected and a current flowing in the electrostatic protection element.

FIG. 6 is a circuit diagram showing an example of a circuit structure of an electrostatic protection element according to a first embodiment.

FIG. 7 is a graph showing a relationship between an inter-terminal voltage between terminals to which the electrostatic protection element according to the first embodiment is connected and a current flowing in the electrostatic protection element.

FIG. 8 is a diagram showing a layout structure in plan view of the electrostatic protection element according to the first embodiment.

FIG. 9 is a cross-sectional view taken along the line A-A in FIG. 8.

FIG. 10 is a graph showing a relationship between a cathode voltage and a cathode current in the electrostatic protection element according to the first embodiment and for example, an electrostatic protection element constituted only by a diode as the related art 2.

FIG. 11 is a cross-sectional view showing a process for producing a semiconductor device according to the first embodiment.

FIG. 12 is a cross-sectional view showing a process for producing a semiconductor device continued from FIG. 11.

FIG. 13 is a cross-sectional view showing a process for producing a semiconductor device continued from FIG. 12.

FIG. 14 is a cross-sectional view showing a process for producing a semiconductor device continued from FIG. 13.

FIG. 15 is a cross-sectional view showing a process for producing a semiconductor device continued from FIG. 14.

FIG. 16 is a cross-sectional view showing a process for producing a semiconductor device continued from FIG. 15.

FIG. 17 is a cross-sectional view showing a process for producing a semiconductor device continued from FIG. 16.

FIG. 18 is a diagram showing a layout structure in plan view of an electrostatic protection element according to a second embodiment.

FIG. 19 is a cross-sectional view taken along the line A-A in FIG. 18.

FIG. 20 is a graph showing a relationship between a cathode voltage and a cathode current in the electrostatic protection element according to the second embodiment, the electrostatic protection element according to the first embodiment, and for example, an electrostatic protection element constituted only by a diode as the related art 2.

FIG. 21 is a diagram showing a layout structure in plan view of an electrostatic protection element according to a third embodiment.

FIG. 22 is a cross-sectional view taken along the line A-A in FIG. 21.

FIG. 23 is a graph showing a relationship between a cathode voltage and a cathode current in the electrostatic protection element according to the third embodiment and the electrostatic protection element according to the first embodiment.

FIG. 24 is a cross-sectional view showing a process for producing the semiconductor device according to the third embodiment.

FIG. 25 is a diagram showing a layout structure in plan view of an electrostatic protection element according to a fourth embodiment.

FIG. 26 is a cross-sectional view taken along the line A-A in FIG. 25.

FIG. 27 is a graph showing a relationship between a cathode voltage and a cathode current in the electrostatic protection element according to the fourth embodiment and the electrostatic protection element according to the first embodiment.

FIG. 28 is a circuit diagram showing a schematic circuit structure of an inverter circuit to be used for controlling a three-phase motor.

FIG. 29 is a cross-sectional view showing a structure in which a p-channel field-effect transistor Qp is formed in an integrated circuit forming region of a semiconductor substrate and an electrostatic protection element ESD is formed in an electrostatic protection element forming region of the same semiconductor substrate.

### DESCRIPTION OF THE PREFERRED EMBODIMENTS

In the embodiments described below, the description is divided into multiple sections or embodiments when required as a matter of convenience. However, these sections or embodiments are not irrelevant to each other unless otherwise explicitly stated, and one relates to the entire or a part of the other as a modification example, details, a supplementary explanation thereof, or the like.

Also, in the embodiments described below, when referring to the number and the like of elements (including number of pieces, numerical value, amount, range, etc.), the number of elements is not limited to a specific number unless otherwise explicitly stated or except the case where the number is apparently limited to a specific number in principle, and a number larger or smaller than the specific number is also applicable.

Further, in the embodiments described below, it goes without saying that the components (including element steps, etc.) are not always indispensable unless otherwise explicitly stated or except the case where it is conceivable that the components are apparently indispensable in principle.

Similarly, in the embodiments described below, when the shape of the components, positional relationship thereof, and the like are mentioned, shapes substantially approximate or similar thereto and the like are included therein unless otherwise explicitly stated or except the case where it is conceivable that they are apparently excluded in principle. The same goes for the numerical value and the range described above.

Further, the same member is denoted by the same reference numeral in principle in all drawings for explaining the embodiments, and the repetitive explanation thereof is omitted. Incidentally, hatching is sometimes given even in plan view so as to make the drawings easy to see.

### First Embodiment

### <Electrostatic Protection Element in Related Art>

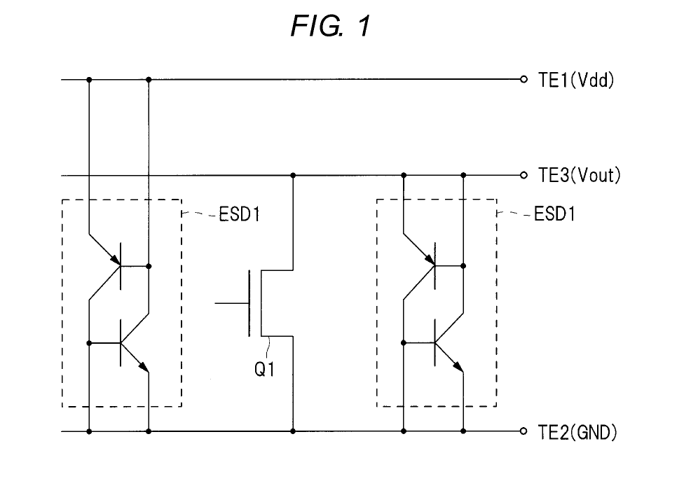

FIG. 1 is a circuit diagram showing an example of a circuit structure of an electrostatic protection element ESD1 in a related art 1. As shown in FIG. 1, the electrostatic protection element ESD1 is provided between a power supply terminal TE1 to which a power supply potential (Vdd) is applied and a ground terminal TE2 to which a reference potential (GND potential) is applied. According to this configuration, even if a large electrostatic noise is applied between the power supply terminal TE1 and the ground terminal TE2, an internal circuit element (not shown) connected between the power supply terminal TE1 and the ground terminal TE2 can be protected. Similarly, the electrostatic protection element ESD1 can also be provided between an output terminal TE3 and the ground terminal TE2. In this case, the electrostatic protection element ESD1 is connected in parallel with a field-effect transistor Q1, which is an output transistor connected between the output terminal TE3 and the ground terminal TE2. Therefore, for example, even if an electrostatic noise is applied between the output terminal TE3 and the ground terminal TE2, by the electrostatic protection element ESD1, the field-effect transistor Q1 connected in parallel with the electrostatic protection element ESD1 can be protected.

Specifically, the electrostatic protection element ESD1 in the related art 1 has, for example, a so-called thyristor structure constituted by an npn bipolar transistor and a pnp bipolar transistor in combination as shown in FIG. 1. When an electrostatic noise is applied to a semiconductor device, the electrostatic protection element ESD1 having this thyristor structure goes into breakdown and enters a snapback state at a lower voltage than the withstand voltage of the internal circuit element (semiconductor element) which is included in the device and should be protected, whereby the inter-terminal voltage is decreased, and also the power consumption of the electrostatic protection element ESD1 can be suppressed to low even if a large current is made to flow. Due to this, according to the semiconductor device having the electrostatic protection element ESD1 with a thyristor structure incorporated therein, even if an electrostatic noise is applied, heat generation of the electrostatic protection element ESD1 is suppressed, so that breakdown of the electrostatic protection element ESD1 can be made hard to Occur.

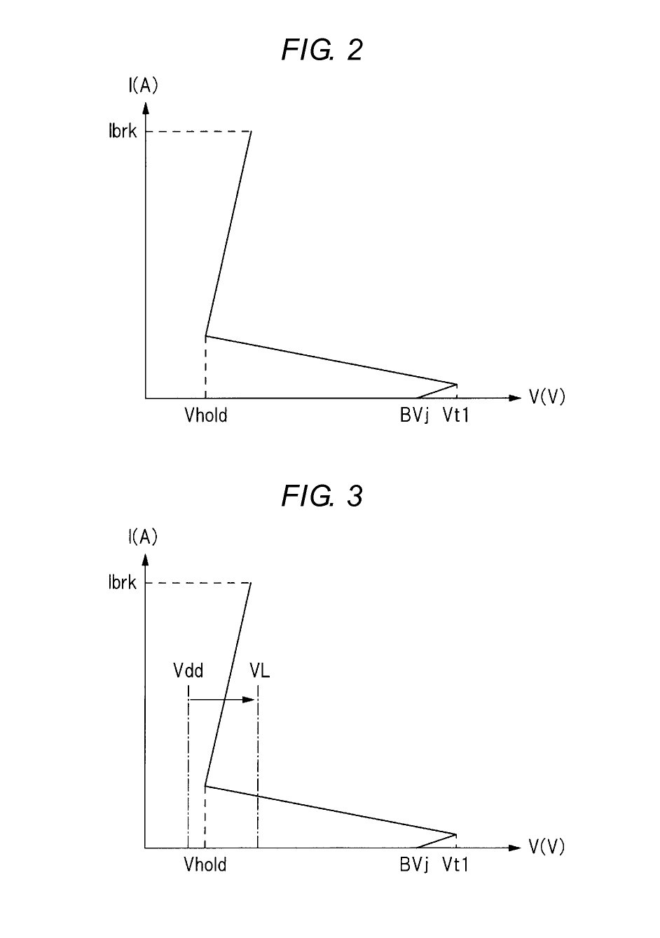

FIG. 2 is a graph showing a relationship between an inter-terminal voltage between terminals to which the electrostatic protection element ESD1 in the related art 1 is connected and a current flowing in the electrostatic protection element ESD1. In FIG. 2, the abscissa represents an inter-terminal voltage, and the ordinate represents a current flowing in the electrostatic protection element ESD1.

In FIG. 2, due to an electrostatic noise or the like, a high voltage is applied between the terminals to which the electrostatic protection element ESD1 is connected, and when this high voltage exceeds the avalanche breakdown voltage BVj, the npn bipolar transistor constituting a part of the electrostatic protection element ESD1 performs an on-operation and goes into a snapback state. At this time, the inter-terminal voltage decreases from a snapback voltage Vt1 to a holding voltage Vhold. Thereafter, the pnp bipolar transistor constituting a part of the electrostatic protection element ESD1 performs an on-operation, whereby a current flowing in the electrostatic protection element ESD1 increases. As a result, the inter-terminal voltage increases to increase the electric power to be applied to the electrostatic protection element ESD1. Due to this, the electrostatic protection element ESD1 generates heat to increase the temperature of the electrostatic protection element ESD1.

In the case where the electric charge amount of the electrostatic noise is relatively small, a collector current of the npn bipolar transistor flowing for releasing an electric charge decreases thereafter to decrease the inter-terminal voltage. As a result, the inter-terminal voltage decreases to the holding voltage Vhold or lower to stop the operation of the electrostatic protection element ESD1. On the other hand, in the case where the electric charge amount of the electrostatic noise is relatively large, a collector current of the npn bipolar transistor flowing for releasing an electric charge continuously increases to increase the temperature of the electrostatic protection element ESD1. Then, the temperature of the electrostatic protection element ESD1 exceeds the breakdown limit to cause breakdown of the electrostatic protection element ESD1. The breakdown current at this time is Ibrk.

Therefore, from the viewpoint that even if an electrostatic noise having a larger electric charge is applied, breakdown of the electrostatic protection element ESD1 is prevented from occurring, the breakdown current (ESD resistance) at which breakdown of the electrostatic protection element ESD1 occurs is required to be large. In terms of this point, the electrostatic protection element ESD1 in the related art 1 has a so-called thyristor structure, and a large voltage drop called “snapback” occurs. Due to this, in the electrostatic protection element ESD1 in the related art 1, the absolute value of the voltage is decreased due to the voltage drop, and thus, the breakdown current can be increased. That is, the electrostatic protection element ESD1 in the related art 1 has an advantage that the ESD resistance can be increased.

However, in the electrostatic protection element ESD1 in the related art 1, for example, as the circuit containing an inductance, in a circuit with a mode in which a voltage is increased above a power supply voltage due to a back electromotive force of the inductance, a large voltage drop is caused by a snapback so that a holding voltage may drop below the voltage of the back electromotive force. In this case, the electrostatic protection element ESD1 may not stop the operation, and therefore, for example, it is difficult to use the electrostatic protection element in a circuit containing an inductance such as a motor. That is, the electrostatic protection element ESD1 in the related art 1 can increase the ESD resistance, but has a problem that the use thereof in a circuit containing an inductance is difficult.

Specifically, FIG. 3 is a graph showing a relationship between an inter-terminal voltage between terminals to which the electrostatic protection element ESD1 in the related art 1 is connected and a current flowing in the electrostatic protection element ESD1 when the electrostatic protection element ESD1 was used in a circuit containing an inductance. As shown in FIG. 3, due to a snapback, an inter-terminal voltage in the electrostatic protection element ESD1 decreases from a snapback voltage Vt1 to a holding voltage Vhold. At this time, in order to avoid not stopping the operation of the electrostatic protection element ESD1, the holding voltage Vhold is set higher than the power supply voltage Vdd. However, in the circuit containing an inductance, the voltage may be increased above the power supply voltage Vdd by a back electromotive force of the inductance, and in this case, the voltage VL of the back electromotive force increases above the holding voltage Vhold, and therefore, the electrostatic protection element ESD1 may not stop the operation.

Due to this, although the electrostatic protection element ESD1 in the related art 1 can increase the ESD resistance by a snapback, since a voltage drop by a snapback is large, the use thereof in a circuit containing an inductance is difficult.

Accordingly, in a circuit containing an inductance, not the electrostatic protection element ESD1 in the related art 1, but an electrostatic protection element ESD2 in a related art 2 which will be described below is used.

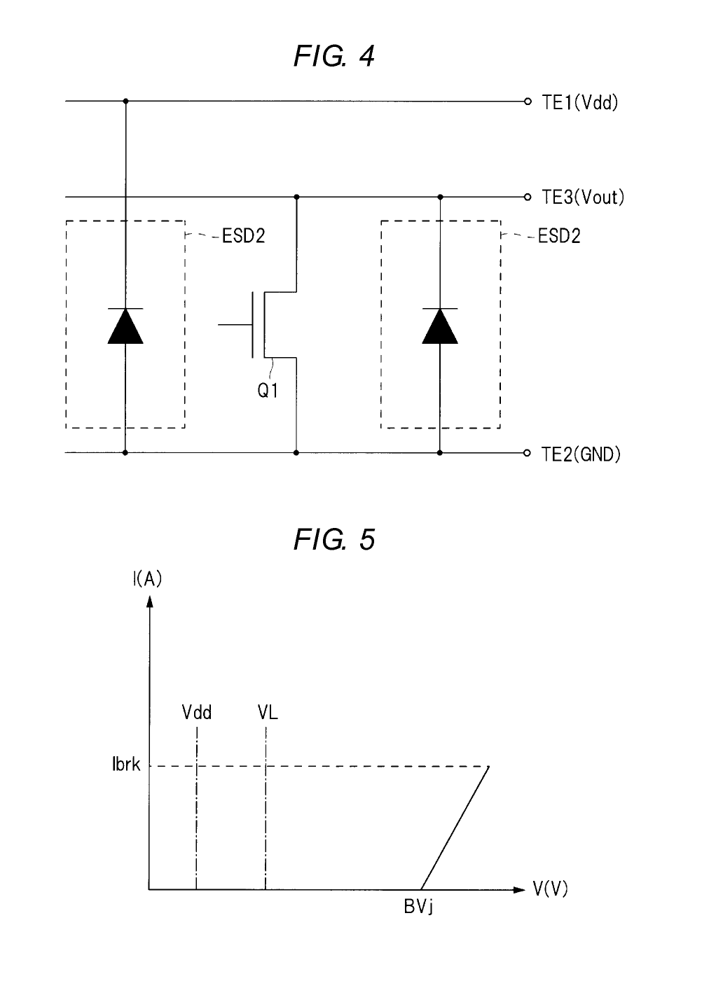

FIG. 4 is a circuit diagram showing an example of a circuit structure of the electrostatic protection element ESD2 in the related art 2. Specifically, the electrostatic protection element ESD2 in the related art 2 is constituted by, for example, a diode as shown in FIG. 4. When attention is paid to, for example, a power supply terminal TE1 and a ground terminal TE2, the electrostatic protection element ESD2 constituted by the diode is inserted between the power supply terminal TE1 and the ground terminal TE2 so that a cathode electrode is connected to the power supply terminal TE1, and an anode electrode is connected to the ground terminal TE2. When an electrostatic noise is applied to a semiconductor device, breakdown of this electrostatic protection element ESD2 constituted by the diode occurs at a lower voltage than the withstand voltage of an internal circuit element (semiconductor element) which is included in the device and should be protected. As a result, by the breakdown of the diode, the internal circuit element can be protected from an electrostatic noise.

FIG. 5 is a graph showing a relationship between an inter-terminal voltage between terminals to which the electrostatic protection element ESD2 in the related art 2 is connected and a current flowing in the electrostatic protection element ESD2. In FIG. 5, the abscissa represents an inter-terminal voltage, and the ordinate represents a current flowing in the electrostatic protection element ESD2.

In FIG. 5, due to an electrostatic noise or the like, a high voltage is applied between the terminals to which the electrostatic protection element ESD2 is connected, and when this high voltage exceeds the avalanche breakdown voltage BVj, avalanche breakdown of the diode constituting the electrostatic protection element ESD2 occurs. Thereafter, when a current flowing in the electrostatic protection element ESD2 increases, the inter-terminal voltage increases to increase the electric power to be applied to the electrostatic protection element ESD2. Due to this, the electrostatic protection element ESD2 generates heat to increase the temperature of the electrostatic protection element ESD2.

In the case where the electric charge amount of the electrostatic noise is relatively small, a breakdown current of the diode flowing for releasing an electric charge does not flow, and as a result, the electrostatic protection element ESD2 constituted by the diode stops the operation. On the other hand, in the case where the electric charge amount of the electrostatic noise is relatively large, a breakdown current of the diode flowing for releasing an electric charge continuously increases to increase the temperature of the electrostatic protection element ESD2. Then, the temperature of the electrostatic protection element ESD2 exceeds the breakdown limit to cause breakdown of the electrostatic protection element ESD2. The breakdown current at this time is Ibrk.

Here, the electrostatic protection element ESD2 in the related art 2 shown in FIG. 5 is constituted only by a diode, and therefore, snapback does not occur unlike the electrostatic protection element ESD1 in the related art 1 shown in FIG. 1. Therefore, as shown in FIG. 5, the inter-terminal voltage of the electrostatic protection element ESD2 does not drop below the power supply voltage Vdd or the voltage VL of a back electromotive force. As a result, according to the electrostatic protection element ESD2 in the related art 2, a snapback does not occur, and therefore, it can be used in a circuit containing an inductance without any problems.

On the other hand, in the electrostatic protection element ESD2 in the related art 2, since a voltage drop by a snapback does not occur as shown in FIG. 5, the absolute value of the inter-terminal voltage increases so that a breakdown current cannot be increased. That is, in the electrostatic protection element ESD2 in the related art 2, since a snapback does not occur, it can be used in a circuit containing an inductance without any problems, however, since a voltage drop by a snapback does not occur, a breakdown current (ESD resistance) cannot be increased, and therefore, there is a room for improvement from the viewpoint of improvement of ESD resistance. Further, the on-resistance of the electrostatic protection element ESD2 of the related art 2 after avalanche breakdown is increased above the on-resistance of the electrostatic protection element ESD1 of the related art 1 after decreasing to the holding voltage Vhold by a snapback.

In this manner, in the electrostatic protection element ESD2 in the related art 2, the breakdown current (ESD resistance) is decreased as compared with the electrostatic protection element ESD1 in the related art 1 because a voltage drop by a snapback does not occur and the on-resistance is increased. Due to this, although the electrostatic protection element ESD2 in the related art 2 can be used in a circuit containing an inductance without any problems, there is a room for improvement from the viewpoint of improvement of ESD resistance.

Therefore, in a first embodiment, from the viewpoint that an electrostatic protection element can be used in a circuit containing an inductance without any problems, an electrostatic protection element containing a diode as the related art 2 described above has been adopted, and further, measures have been taken for increasing the ESD resistance. Hereinafter, a technical idea of the first embodiment in which the measures have been taken will be described with reference to the accompanying drawings.

### <Basic Idea of First Embodiment>

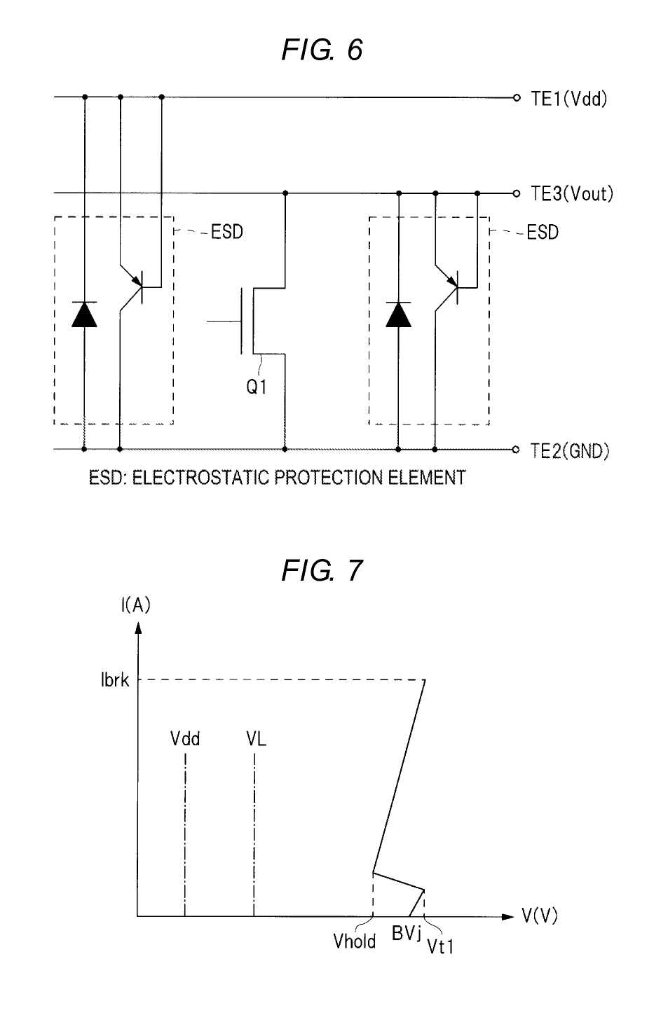

FIG. 6 is a circuit diagram showing an example of a circuit structure of an electrostatic protection element ESD according to the first embodiment. As shown in FIG. 6, an electrostatic protection element ESD is provided between a power supply terminal TE1 to which a power supply potential (Vdd) is applied and a ground terminal TE2 to which a reference potential (GND potential) is applied. Similarly, the electrostatic protection element ESD can also be provided between an output terminal TE3 and the ground terminal TE2. In this case, the electrostatic protection element ESD is connected in parallel with a field-effect transistor Q1, which is an output transistor connected between the output terminal TE3 and the ground terminal TE2.

Specifically, the electrostatic protection element ESD according to the first embodiment is constituted by, for example, as shown in FIG. 6, a diode and a pnp bipolar transistor. When attention is paid to, for example, the power supply terminal TE1 and the ground terminal TE2, the diode is inserted between the power supply terminal TE1 and the ground terminal TE2 so that a cathode terminal is connected to the power supply terminal TE1, and an anode terminal is connected to the ground terminal TE2. Further, in the first embodiment, also the pnp bipolar transistor is inserted between the power supply terminal TE1 and the ground terminal TE2. Specifically, the pnp bipolar transistor is inserted between the power supply terminal TE1 and the ground terminal TE2 so that both of an emitter terminal and a base terminal of the pnp bipolar transistor are connected to the power supply terminal TE1, and a collector terminal of the pnp bipolar transistor is connected to the ground terminal TE2. According to this configuration, the electrostatic protection element ESD of the first embodiment can be used in a circuit containing an inductance without any problems in the same manner as the related art 2 described above, and also the breakdown current (ESD resistance) can be improved as compared with the related art 2 described above. In other words, in the first embodiment, as the electrostatic protection element ESD, by providing the pnp bipolar transistor so as to be connected in parallel with the diode, the breakdown current (ESD resistance) can be further improved while maintaining the usefulness that the electrostatic protection element can be used in a circuit containing an inductance without any problems. That is, the essence of the basic idea of the first embodiment resides in that the electrostatic protection element ESD is configured to include the pnp bipolar transistor so as to be connected in parallel with the diode. In other words, the essence of the basic idea of the first embodiment resides in that the electrostatic protection element ESD is constituted by the diode parasitically provided with the pnp bipolar transistor.

Hereinafter, the basic idea of the first embodiment will be described in detail. FIG. 7 is a graph showing a relationship between an inter-terminal voltage between terminals to which the electrostatic protection element ESD according to the first embodiment is connected and a current flowing in the electrostatic protection element ESD. In FIG. 7, the abscissa represents an inter-terminal voltage, and the ordinate represents a current flowing in the electrostatic protection element ESD.

In FIG. 7, due to an electrostatic noise or the like, a high voltage is applied between the terminals to which the electrostatic protection element ESD is connected, and when this high voltage exceeds the avalanche breakdown voltage BVj, in the diode constituting a part of the electrostatic protection element ESD, avalanche breakdown occurs. In the first embodiment, an electron generated by the avalanche breakdown is injected into the power supply terminal TE1 (a cathode terminal of the diode). At this time, the first embodiment is configured such that this electron flows in a base region of the pnp bipolar transistor, and therefore, the electron flows through the base resistance of the base region. As a result, a potential difference equal to or more than a given value occurs between the emitter region and the base region of the pnp bipolar transistor, and thus, the pnp bipolar transistor performs an on-operation. As a result, the inter-terminal voltage of the electrostatic protection element ESD decreases from a snapback voltage Vt1 to a holding voltage Vhold.

Here, the feature of the electrostatic protection element ESD according to the first embodiment resides in that the semiconductor element which performs an on-operation is constituted by not a thyristor or an npn bipolar transistor, but a pnp bipolar transistor. In this case, a pnp bipolar transistor has a property that a voltage drop by a snapback is smaller than a thyristor or an npn bipolar transistor. As a result, in the electrostatic protection element ESD according to the first embodiment, even if a voltage drop by a snapback occurs, as shown in the related art 1 described above, a large voltage drop by a snapback does not occur. Due to this, as shown in FIG. 7, the holding voltage Vhold does not drop below the power supply voltage Vdd or the voltage VL of a back electromotive force of the inductance. As a result, according to the electrostatic protection element ESD of the first embodiment, even if a voltage drop by a snapback occurs, by using a pnp bipolar transistor, the absolute value of the voltage drop is limited to a small range, and therefore, the electrostatic protection element ESD according to the first embodiment can be used in a circuit containing an inductance without any problems.

Thereafter, when a current flowing in the electrostatic protection element ESD increases, the inter-terminal voltage increases to increase the electric power to be applied to the electrostatic protection element ESD. Due to this, the electrostatic protection element ESD generates heat to increase the temperature of the electrostatic protection element ESD.

In the case where the electric charge amount of the electrostatic noise is relatively small, a collector current of the pnp bipolar transistor flowing for releasing an electric charge decreases thereafter to decrease the inter-terminal voltage. As a result, the inter-terminal voltage decreases to the holding voltage Vhold or lower to stop the operation of the electrostatic protection element ESD. On the other hand, in the case where the electric charge amount of the electrostatic noise is relatively large, a collector current of the pnp bipolar transistor flowing for releasing an electric charge continuously increases to increase the temperature of the electrostatic protection element ESD. Then, the temperature of the electrostatic protection element ESD exceeds the breakdown limit to cause breakdown of the electrostatic protection element ESD. The breakdown current at this time is Ibrk.

Here, in the electrostatic protection element ESD according to the first embodiment, as shown in FIG. 7, a slight voltage drop by a snapback occurs although the range is small. Due to this, the electrostatic protection element ESD according to the first embodiment can improve the ESD resistance as compared with the electrostatic protection element ESD2 in which a snapback does not occur as in the related art 2 described above. That is, the electrostatic protection element ESD according to the first embodiment can further improve the breakdown current (ESD resistance) while maintaining the usefulness that the electrostatic protection element can be used in a circuit containing an inductance without any problems by providing the pnp bipolar transistor so as to be connected in parallel with the diode. Further, in the first embodiment, the on-resistance of the electrostatic protection element ESD after decreasing to the holding voltage Vhold by a snapback is smaller than the on-resistance of the electrostatic protection element ESD2 of the related art 2 after avalanche breakdown. As a result, according to the electrostatic protection element ESD of the first embodiment, by the synergistic effect of the following points that a voltage drop by a snapback occurs although the voltage drop is small and that the on-resistance is decreased by the on-operation of the pnp bipolar transistor, the ESD resistance can be improved as compared with the electrostatic protection element ESD2 in the related art 2 described above.

The basic idea of the first embodiment described above can be summarized as follows. For example, when attention is paid only to the point that the ESD resistance of the electrostatic protection element is improved, as in the related art 1 described above, the electrostatic protection element ESD1 can be constituted by a thyristor or the like in which a voltage drop by a snapback is large. However, if the electrostatic protection element ESD1 of the related art 1 is applied to a circuit containing an inductance, the voltage is increased above the power supply voltage Vdd by a back electromotive force of the inductance. In this case, the voltage VL of the back electromotive force is above the snapback holding voltage Vhold, and thus, the electrostatic protection element ESD1 does not stop the operation. Therefore, in order to avoid this inconvenience, for example, as in the related art 2, it is conceivable to constitute the electrostatic protection element ESD2 by a diode in which a snapback does not occur. However, in the case of this related art 2, it is difficult to improve the ESD resistance due to the point that a snapback does not occur and the point that the on-resistance is increased.

In view of this, the present inventors paid attention to a pnp bipolar transistor. That is, the present inventors paid attention to the point that a pnp bipolar transistor has a property that a voltage drop by a snapback is smaller than a thyristor or an npn bipolar transistor, and realized the electrostatic protection element ESD capable of further improving the breakdown current (ESD resistance) while maintaining the usefulness that the electrostatic protection element ESD can be used in a circuit containing an inductance without any problems by constituting the electrostatic protection element ESD by a pnp bipolar transistor and a diode in combination.

That is, the basic idea of the first embodiment is that a diode in which a snapback does not occur is used as a base structure, and a pnp bipolar transistor in which a slight voltage drop occurs by a snapback is used in combination with this diode. Due to this, an advantage that the inter-terminal voltage can be decreased and an advantage that the on-resistance can be decreased as compared with the case where the electrostatic protection element is constituted by a diode alone can be obtained. As a result, the ESD resistance of the electrostatic protection element ESD can be improved. On the other hand, a voltage drop by the on-operation of the pnp bipolar transistor can be made smaller than a voltage drop in a thyristor or an npn bipolar transistor, and therefore, the electrostatic protection element ESD can be used without any problems in a circuit containing an inductance in which a back electromotive force is generated. That is, the feature of the first embodiment resides in that the ESD resistance is improved within a range that the use thereof in a circuit containing an inductance is not impeded by paying attention to the point that a voltage drop by a snapback in the pnp bipolar transistor is slight.

### <Structure of Electrostatic Protection Element According to First Embodiment>

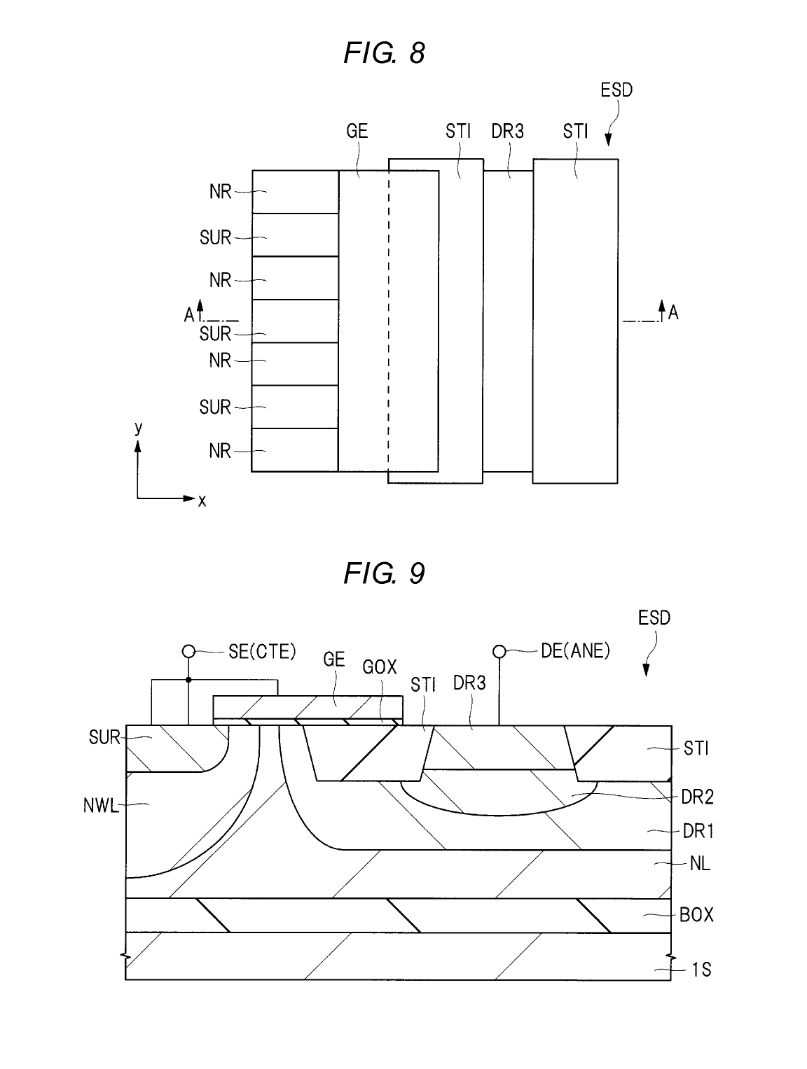

Next, the structure of the electrostatic protection element ESD embodying the basic idea of the first embodiment will be described. FIG. 8 is a diagram showing a layout structure in plan view of the electrostatic protection element ESD according to the first embodiment. In FIG. 8, the electrostatic protection element ESD according to the first embodiment includes a pair of field insulating regions STI extending in the y direction parallel to each other on a semiconductor substrate, and a high concentration drain region DR3 extending in the y direction is disposed so as to be interposed between the pair of field insulating regions STI. Further, for example, as shown in FIG. 8, a gate electrode GE is formed so as to overlap with a part of the field insulating region STI on the left side of the pair of field insulating regions STI, and this gate electrode GE extends in the y direction.

Further, multiple source unit regions SUR are provided adjacent to the gate electrode GE, and these multiple source unit regions SUR are arranged at a predetermined interval in the y direction in which the gate electrode GE extends. In each of the multiple spaces with a predetermined interval, an n-type power supply region NR is disposed. At this time, the multiple source unit regions SUR are electrically connected to one another, and from the multiple source unit regions SUR, a source region is formed. On the other hand, the n-type power supply regions NR disposed in the multiple spaces, respectively, are also electrically connected to one another.

FIG. 9 is a cross-sectional view taken along the line A-A in FIG. 8. As shown in FIG. 9, the electrostatic protection element ESD according to the first embodiment is formed on an SOI substrate. Specifically, on a support substrate 1S, a buried insulating layer BOX is formed, and on the buried insulating layer BOX, an n-type semiconductor layer NL is formed. That is, by the support substrate 1S, the buried insulating layer BOX, and the n-type semiconductor layer NL, the SOI substrate is constituted. Incidentally, in FIG. 9, an example in which the electrostatic protection element ESD is formed on the SOI substrate is shown, however, the technical idea of the first embodiment is not limited thereto, and it is also possible to form the electrostatic protection element ESD on a usual semiconductor substrate (for example, a p-type semiconductor substrate).

On the n-type semiconductor layer NL, a low concentration drain region DR1 composed of a p-type semiconductor region is formed, and further on the n-type semiconductor layer NL, an n-type well NWL composed of an n-type semiconductor region is formed apart from the low concentration drain region DR1. On the surface of the n-type semiconductor layer NL, a pair of field insulating regions STI are formed so as to be included in the low concentration drain region DR1. Each field insulating region STI is formed to have, for example, a trench structure in which an insulating film typified by a silicon oxide film is buried in a groove. Subsequently, a medium concentration drain region DR2 composed of a p-type semiconductor region is formed so as to straddle the pair of field insulating regions STI, and further, a high concentration drain region DR3 composed of a p⁺-type semiconductor region is formed so as to be included in the medium concentration drain region DR2. Here, the low concentration drain region DR1, the medium concentration drain region DR2, and the high concentration drain region DR3 are collectively referred to as “drain region”.

On the other hand, the source unit region SUR composed of, for example, a p⁺-type semiconductor region is formed so as to be included in the n-type well NWL. Further, a gate insulating film GOX composed of, for example, a silicon oxide film is formed from a region which overlaps with a part of the source unit region SUR, passing over the n-type semiconductor layer NL, and further over a part of the field insulating region STI on the left side. On this gate insulating film GOX, a gate electrode GE composed of, for example, a polysilicon film doped with a conductive impurity is formed.

In the electrostatic protection element ESD according to the first embodiment configured as shown in FIGS. 8 and 9, the multiple source unit regions SUR, the multiple n-type power supply regions NR, and the gate electrode GE are electrically connected to one another through, for example, a wiring via a plug. As a result, the source terminal SE shown in FIG. 9 is electrically connected to the source unit regions SUR, the n-type power supply regions NR, and the gate electrode GE. In particular, each of the multiple n-type power supply regions NR is connected to the n-type well NWL composed of the same n-type semiconductor region, and therefore, the source terminal SE is electrically connected also to the n-type well NWL through the n-type power supply regions NR. At this time, the impurity concentration in the n-type power supply regions NR is higher than the impurity concentration in, for example, the n-type well NWL, and the n-type power supply regions NR have a function of ensuring an Ohmic contact with the plug disposed, for example, over the multiple n-type power supply regions NR and the multiple source unit regions SUR. On the other hand, the high concentration drain region DR3 is electrically connected to the drain terminal DE through, for example, a wiring via a plug.

Incidentally, in the first embodiment, an example in which the n-type power supply region NR is formed between each of the source unit regions SUR arranged at a predetermined interval is described, however, the configuration is not limited thereto, and for example, a configuration in which the n-type power supply region NR is not provided between each of the multiple source unit regions SUR, and the n-type well NWL is exposed between each of the multiple source unit regions SUR may be adopted. It is also possible to modify this configuration such that, for example, the n-type power supply region NR is constituted as a part of the n-type well NWL.

The electrostatic protection element ESD according to the first embodiment configured as described above includes a pn junction diode and a pnp bipolar transistor. Specifically, the pn junction diode is formed from a pn junction which is formed in a boundary region between the n-type semiconductor layer NL and the drain region (p-type semiconductor region). In this pn junction diode, the source region (multiple source unit regions SUR) electrically connected to the n-type semiconductor layer NL through the n-type well NWL is used as a cathode region, and the drain region is used as an anode region. Therefore, as shown in FIG. 9, the source terminal SE functions as a cathode terminal CTE, and the drain terminal DE functions as an anode terminal ANE.

Further, in the electrostatic protection element ESD according to the first embodiment, the source region (multiple source unit regions SUR) is used as an emitter region, and the n-type well and the n-type semiconductor layer NL are used as abase region, and further, the pnp bipolar transistor in which the drain region is used as a collector region is formed.

Accordingly, the electrostatic protection element ESD according to the first embodiment has the same structure as that of a field-effect transistor, but is configured such that the source region, the n-type well NWL, and the gate electrode GE are electrically connected to one another, and therefore, substantially functions as a semiconductor element in which a pn junction diode and a pnp bipolar transistor are combined.

Hereinafter, the operation of the electrostatic protection element ESD according to the first embodiment functioning as a semiconductor element in which a pn junction diode and a pnp bipolar transistor are combined will be described with reference to FIG. 9.

### <Operation of Electrostatic Protection Element ESD in First Embodiment>

First, in FIG. 9, for example, the source terminal SE functioning as the cathode terminal CTE of the electrostatic protection element ESD is connected to the power supply potential, and the drain terminal DE functioning as the anode terminal ANE of the electrostatic protection element ESD is connected to the ground potential. In this case, the diode included in the electrostatic protection element ESD is connected in the reverse direction between the power supply potential and the ground potential, and therefore, in the electrostatic protection element ESD including the diode, a current does not flow in a normal state.

Here, an electrostatic noise having a plus charge on the power supply potential side and a minus charge on the ground potential side is assumed to be generated. At this time, the voltage of the electrostatic noise is much higher than a potential difference between the power supply potential and the ground potential, and this high voltage is applied to the diode. That is, in FIG. 9, a high voltage due to the electrostatic noise is applied as a reverse bias to the pn junction diode formed in the boundary region between the drain region and the n-type semiconductor layer NL.

If the high voltage due to the electrostatic noise exceeds the avalanche withstand voltage of the pn junction diode, avalanche breakdown occurs in the pn junction diode, and a hole and an electron are generated. The generated hole flows from the drain region to the drain terminal DE. On the other hand, the generated electron flows from the n-type semiconductor layer NL to the source terminal SE through the n-type well NWL and the n-type power supply region NR.

At this time, when attention is paid to the flow of the electron, the electron flows from the n-type semiconductor layer NL and passes through the n-type well NWL and the n-type power supply region NR, however, these regions constitute the base region of the pnp bipolar transistor. Due to this, the electron generated by the avalanche breakdown passes through the base region of the pnp bipolar transistor.

Here, the base region of the pnp bipolar transistor has a base resistance, and therefore, when an electron flows through this base resistance, a voltage drop occurs. Accordingly, a potential difference occurs between the source region functioning as the emitter region and the n-type semiconductor region (a region composed of the n-type well NWL, the n-type semiconductor layer NL, and the n-type power supply region NR) functioning as the base region. Then, when the potential difference between the emitter region and the base region exceeds a predetermined value, the pnp bipolar transistor turns on. Due to this, a current flows in the collector region from the emitter region of the pnp bipolar transistor. That is, by the on-operation of the pnp bipolar transistor, a current flows from the source terminal SE (cathode terminal CTE) to the drain terminal DE (anode terminal ANE).

As a result, the inter-terminal voltage of the electrostatic protection element ESD decreases from a snapback voltage Vt1 to a holding voltage Vhold. Thereafter, when a current flowing in the electrostatic protection element ESD increases, the inter-terminal voltage increases to increase the electric power to be applied to the electrostatic protection element ESD. Due to this, the electrostatic protection element ESD generates heat to increase the temperature of the electrostatic protection element ESD.

In the case where the electric charge amount of the electrostatic noise is relatively small, a collector current of the pnp bipolar transistor flowing for releasing an electric charge decreases thereafter to decrease the inter-terminal voltage. As a result, the inter-terminal voltage decreases to the holding voltage Vhold or lower to stop the operation of the electrostatic protection element ESD. On the other hand, in the case where the electric charge amount of the electrostatic noise is relatively large, a collector current of the pnp bipolar transistor flowing for releasing an electric charge continuously increases to increase the temperature of the electrostatic protection element ESD. Then, the temperature of the electrostatic protection element ESD exceeds the breakdown limit to cause breakdown of the electrostatic protection element ESD. The breakdown current at this time corresponds to the ESD resistance. As described above, the electrostatic protection element ESD according to the first embodiment operates.

### Effect of First Embodiment

In the electrostatic protection element ESD according to the first embodiment, the semiconductor element which performs an on-operation is constituted by not a thyristor or an npn bipolar transistor, but a pnp bipolar transistor. In this case, in a pnp bipolar transistor, a voltage drop by a snapback is smaller than in a thyristor or an npn bipolar transistor. As a result, as shown in FIG. 7, the holding voltage Vhold can be prevented from dropping below the power supply voltage Vdd or the voltage VL of a back electromotive force of the inductance. Due to this, according to the electrostatic protection element ESD of the first embodiment, even if a voltage drop by a snapback occurs, by using a pnp bipolar transistor, the absolute value of the voltage drop is limited to a small range, and therefore, an advantage that the electrostatic protection element ESD according to the first embodiment can be used in a circuit containing an inductance without any problems can be maintained.

In the electrostatic protection element ESD according to the first embodiment, as shown in FIG. 7, a slight voltage drop by a snapback occurs although the range is small. Due to this, the electrostatic protection element ESD according to the first embodiment can improve the ESD resistance as compared with an electrostatic protection element in which a snapback does not occur. That is, the electrostatic protection element ESD according to the first embodiment can further improve the breakdown current (ESD resistance) while maintaining the usefulness that the electrostatic protection element can be used in a circuit containing an inductance without any problems by providing the pnp bipolar transistor so as to be connected in parallel with the diode.

Further, in the first embodiment, the on-resistance of the electrostatic protection element ESD after decreasing to the holding voltage Vhold by a snapback is smaller than, for example, the on-resistance of the electrostatic protection element ESD2 of the related art 2 after avalanche breakdown. As a result, according to the electrostatic protection element ESD of the first embodiment, by the synergistic effect of the following points that a voltage drop by a snapback occurs although the voltage drop is small and that the on-resistance is decreased by the on-operation of the pnp bipolar transistor, the ESD resistance can be improved.

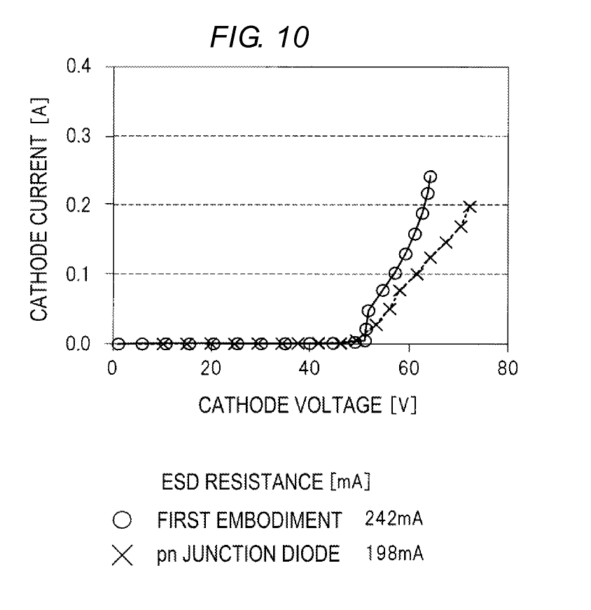

Hereinafter, specific experimental results will be described. FIG. 10 is a graph showing a relationship between a cathode voltage and a cathode current in the electrostatic protection element according to the first embodiment and, for example, an electrostatic protection element constituted only by a diode as the related art 2.

In FIG. 10, the abscissa represents a cathode voltage (V), and the ordinate represents a cathode current (A). The ∘ marks correspond to the electrostatic protection element according to the first embodiment, and the X marks correspond to the electrostatic protection element constituted only by a pn junction diode.

As shown in FIG. 10, it is found that in the electrostatic protection element according to the first embodiment, the pnp bipolar transistor operates, and therefore, a snapback occurs, although the snapback is small, and also the on-resistance is decreased. Therefore, according to the electrostatic protection element of the first embodiment, the ESD resistance corresponding to the breakdown current can be improved as compared with the electrostatic protection element constituted only by a pn junction diode. Specifically, as shown in FIG. 10, it is found that the ESD resistance of the electrostatic protection element constituted only by a pn junction diode is 198 mA, however, the ESD resistance of the electrostatic protection element according to the first embodiment is 242 mA. From these results, it is found that according to the electrostatic protection element of the first embodiment constituted by a pn junction diode and a pnp bipolar transistor in combination, the ESD resistance can be improved as compared with the electrostatic protection element constituted only by a pn junction diode.

### <Method for Producing Semiconductor Device According to First Embodiment>

Next, a method for producing a semiconductor device including the electrostatic protection element according to the first embodiment will be described with reference to the accompanying drawings.

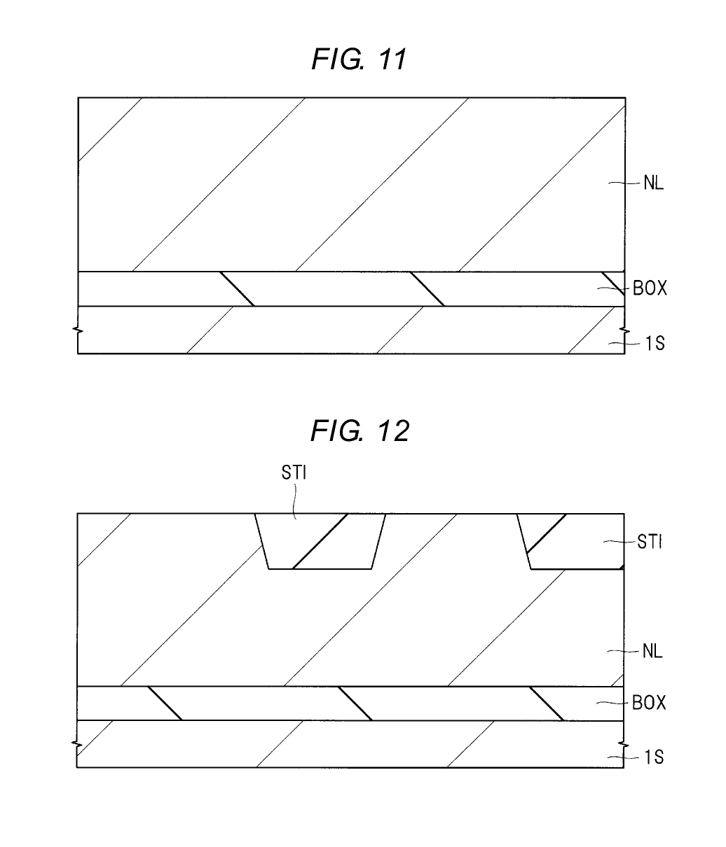

First, as shown in FIG. 11, an SOI substrate is prepared. This SOI substrate is composed of, for example, a support substrate 1S, a buried insulating layer BOX formed on the support substrate 1S, and an n-type semiconductor layer NL formed on the buried insulating layer BOX. Here, for example, the support substrate 1S is composed of silicon, and the buried insulating layer BOX is composed of a silicon oxide film. Further, the n-type semiconductor layer NL is formed by, for example, doping a silicon layer with an n-type impurity (donor) such as phosphorus (P) or arsenic (As). Incidentally, the impurity concentration in the n-type semiconductor layer NL is, for example, about 2.0×10¹⁵ (cm⁻³).

Subsequently, as shown in FIG. 12, a pair of field insulating regions STI are formed apart from each other on the surface of the n-type semiconductor layer NL. The field insulating region STI is formed, for example, as follows. A groove is formed on the surface of the n-type semiconductor layer NL by using a photolithographic technique or an etching technique, and thereafter a silicon oxide film is formed on the n-type semiconductor layer NL by using a CVD (Chemical Vapor Deposition) method so as to bury the silicon oxide film in the groove. Thereafter, an unnecessary silicon oxide film formed on the surface of the n-type semiconductor layer NL is removed by, for example, a CMP (Chemical Mechanical Polishing) method, whereby the silicon oxide film is left only in the groove. In this manner, the field insulating region STI composed of a structure in which a silicon oxide film is buried in a groove can be formed.

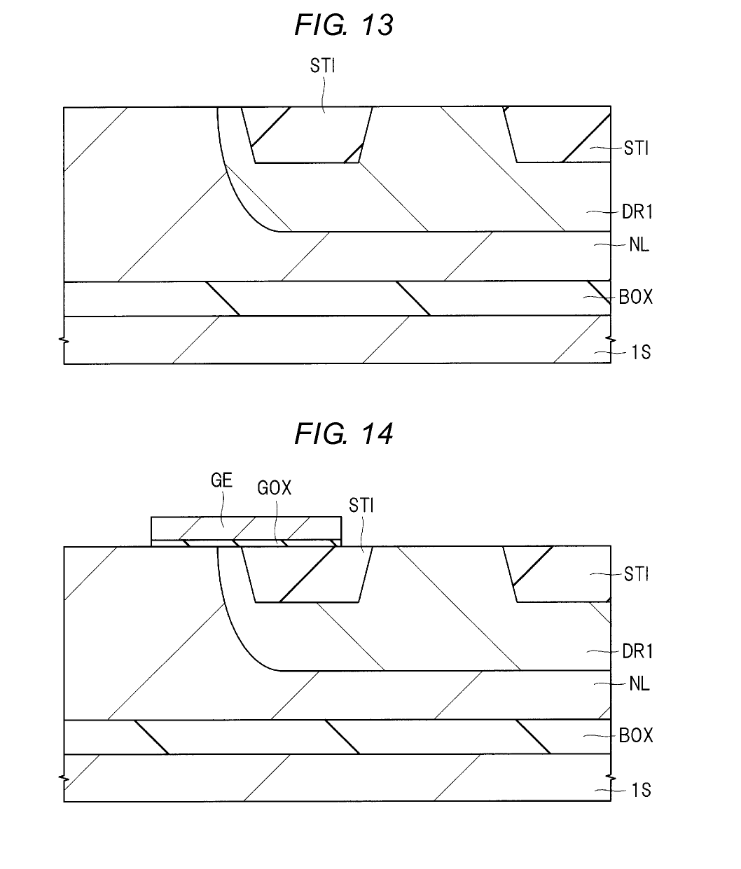

Subsequently, as shown in FIG. 13, by using a photolithographic technique or an ion implantation method, a low concentration drain region DR1 composed of a p-type semiconductor region is formed so as to include the pair of field insulating regions STI in the n-type semiconductor layer NL. Specifically, the low concentration drain region DR1 is formed by, for example, doping the n-type semiconductor layer NL with a p-type impurity (acceptor) such as boron (B), followed by a heat treatment for activating the doped p-type impurity. The impurity concentration in this low concentration drain region DR1 is, for example, about 2.0×10¹⁵ (cm³) to 2.0×10¹⁶ (cm⁻³).

Subsequently, as shown in FIG. 14, agate insulating film GOX is formed on the surface of the n-type semiconductor layer NL. The gate insulating film. GOX is formed from, for example, a silicon oxide film, however, it is not limited thereto, and for example, the gate insulating film GOX may be formed from a high dielectric film having a higher dielectric constant than a silicon oxide film typified by a hafnium oxide film. Thereafter, after forming a polysilicon film on the gate insulating film GOX, by using a photolithographic technique or an etching technique, this polysilicon film is patterned, whereby a gate electrode GE is formed. This gate electrode GE is, for example, formed so as to overlap with a part of the field insulating region STI on the left side of the pair of field insulating regions STI as shown in FIG. 14.

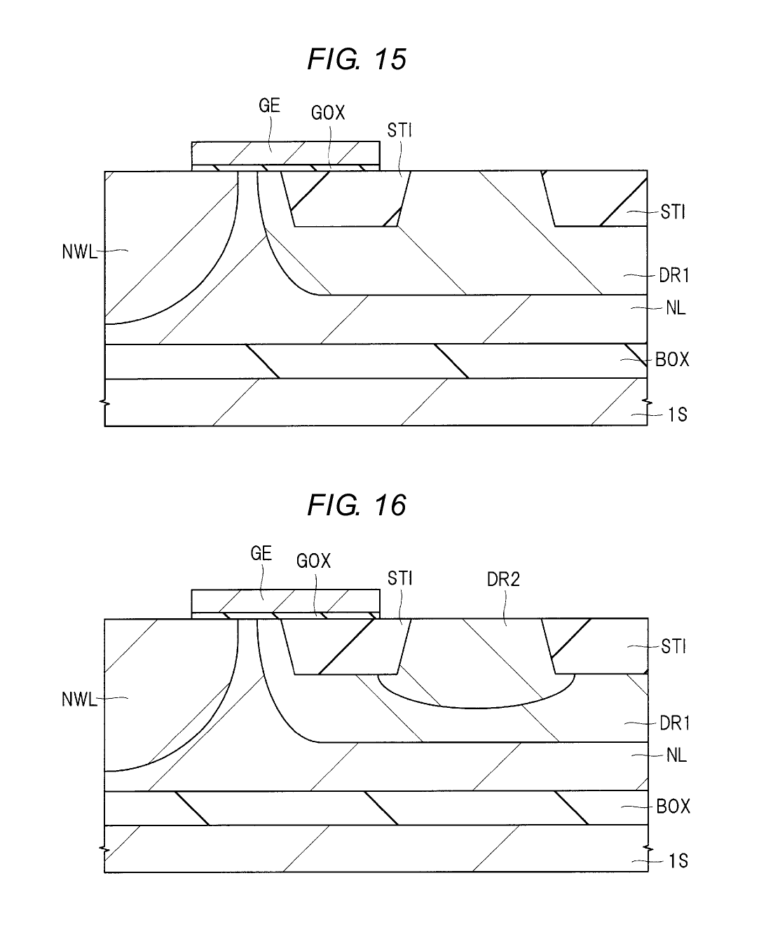

Then, as shown in FIG. 15, by using a photolithographic technique or an ion implantation method, an n-type well NWL is formed apart from the low concentration drain region DR1 in the n-type semiconductor layer NL. Specifically, the n-type well NWL is formed by, for example, doping the n-type semiconductor layer NL with an n-type impurity such as phosphorus (P) or arsenic (As), followed by a heat treatment for activating the doped n-type impurity. The impurity concentration in this n-type well NWL is, for example, about 1.0×10¹⁶ (cm⁻³) to 5.0×10¹⁷ (cm⁻³).

Subsequently, as shown in FIG. 16, by using a photolithographic technique or an ion implantation method, a medium concentration drain region DR2 composed of a p-type semiconductor region is formed so as to be included in the low concentration drain region DR1 and also to straddle the pair of field insulating regions STI. Specifically, the medium concentration drain region DR2 is formed by, for example, doping the low concentration drain region DR1 with a p-type impurity such as boron (B), followed by a heat treatment for activating the doped p-type impurity. The impurity concentration in this medium concentration drain region DR2 is, for example, about 5.0×10¹⁶ (cm⁻³) to 1.0×10¹⁸ (cm⁻³).

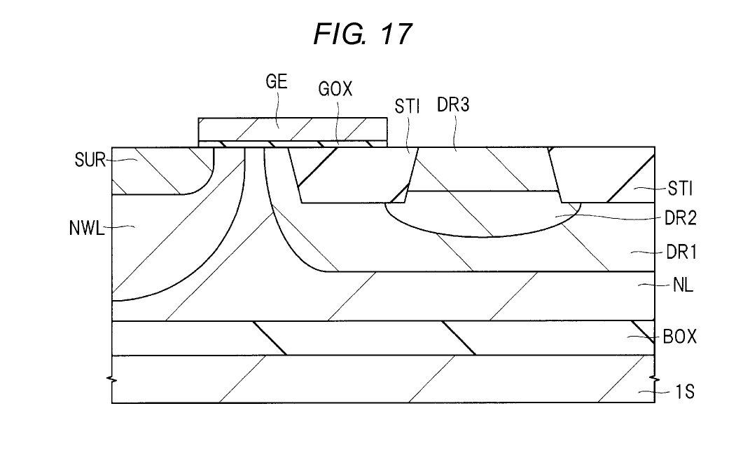

Subsequently, as shown in FIG. 17, by using a photolithographic technique or an ion implantation method, a high concentration drain region DR3 composed of a p⁺-type semiconductor region is formed so as to be included in the medium concentration drain region DR2 and also to be interposed between the pair of field insulating regions STI. Specifically, the high concentration drain region DR3 is formed by, for example, doping the medium concentration drain region DR2 with a p-type impurity such as boron (B), followed by a heat treatment for activating the doped p-type impurity. The impurity concentration in this high concentration drain region DR3 is, for example, about 1.0×10¹⁹ (cm⁻³) to 1.0×10²⁰ (cm⁻³).

Further, as shown in FIG. 8, by using a photolithographic technique or an ion implantation method, multiple source unit regions SUR composed of a p⁺-type semiconductor region are formed so as to be adjacent to the gate electrode GE and to be arranged at a predetermined interval in the y direction in which the gate electrode GE extends. Further, an n-type power supply region NR is formed in each of the multiple spaces with a predetermined interval. Specifically, the multiple source unit regions SUR are formed by, for example, doping the n-type well NWL with a p-type impurity such as boron (B), followed by a heat treatment for activating the doped p-type impurity. The impurity concentration in this source unit region SUR is, for example, about 1.0×10¹⁹ (cm⁻³) to 1.0×10²⁰ (cm⁻³). On the other hand, the n-type power supply region NR is formed by, for example, doping the n-type well NWL with an n-type impurity such as phosphorus (P) or arsenic (As), followed by a heat treatment for activating the doped n-type impurity. The impurity concentration in this n-type power supply region NR is, for example, about 1.0×10¹⁹ (cm⁻³) to 1.0×10²⁰ (cm⁻³). Therefore, the impurity concentration in the power supply region NR is higher than the impurity concentration in the n-type well NWL. At this time, the n-type well NWL and the n-type power supply region NR are both composed of an n-type semiconductor region, and therefore, are electrically connected to each other.

Thereafter, by using, for example, a CVD method, an interlayer insulating film composed of a silicon oxide film is formed so as to cover the gate electrode GE, and a plug is formed on this interlayer insulating film. Then, on the interlayer insulating film having the plug formed thereon, a wiring is formed. At this time, in the first embodiment, for example, as shown in FIG. 9, the plug and the wiring are formed so that the multiple source unit regions SUR, the n-type power supply region NR, and the gate electrode GE are electrically connected to one another. By doing this, a source terminal SE functioning as a cathode terminal CTE, to which the multiple source unit regions SUR, the n-type power supply region NR, and the gate electrode GE are electrically connected, can be formed. On the other hand, a drain terminal DE functioning as an anode terminal ANE, to which the high concentration drain region DR3 is electrically connected through the plug and the wiring, can be formed.

As described above, according to the first embodiment, an electrostatic protection element, which has the same structure as that of a field-effect transistor, but substantially functions as a semiconductor element in which a pn junction diode and a pnp bipolar transistor are combined, can be produced by electrically connecting a source region (multiple source unit regions SUR), an n-type well NWL, and a gate electrode GE to one another.

### Second Embodiment

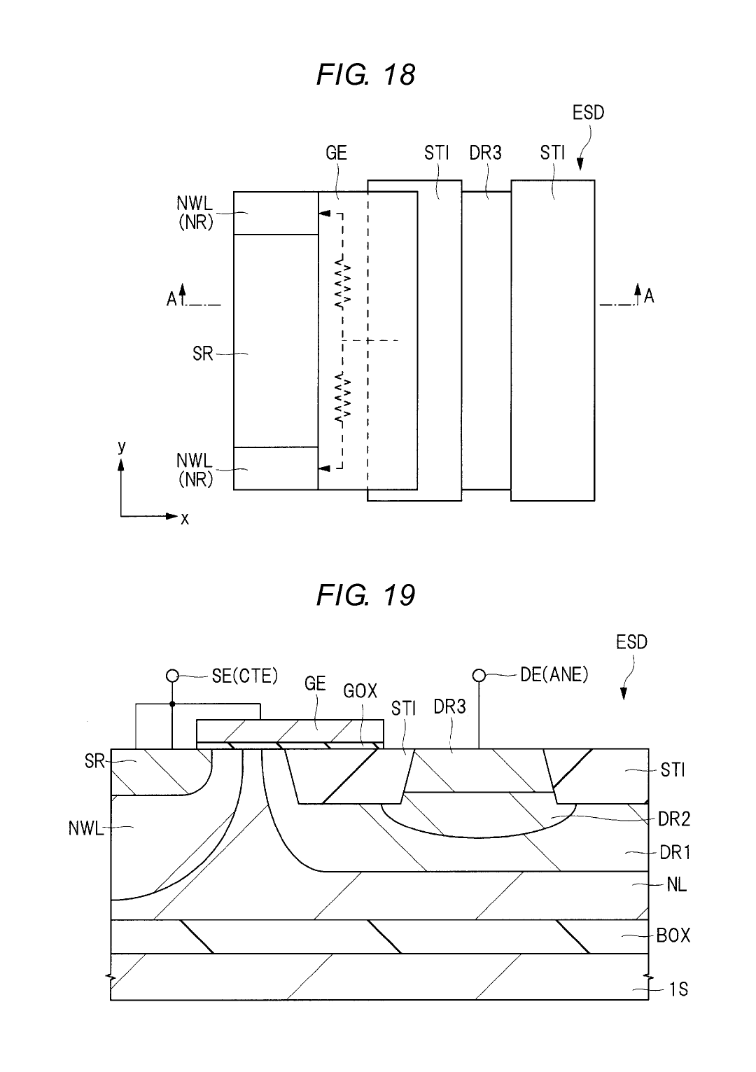

In the first embodiment described above, for example, as shown in FIG. 8, an example of the structure of the electrostatic protection element ESD in which the multiple source unit regions SUR are arranged at a predetermined interval in the y direction in which the gate electrode GE extends, and also the n-type power supply region NR is disposed in each of the multiple spaces with a predetermined interval is described. In the second embodiment, for example, as shown in FIG. 18, an example in which the source region SR extends in the extending direction of the gate electrode GE, and a pair of n-type power supply regions NR are disposed in both end portions in the extending direction of the source region SR will be described.

### <Structure of Electrostatic Protection Element According to Second Embodiment>

The structure of the electrostatic protection element ESD according to the second embodiment is substantially the same as the structure of the electrostatic protection element ESD according to the first embodiment described above, and therefore, a different point will be mainly described.

FIG. 18 is a diagram showing a layout structure in plan view of the electrostatic protection element ESD according to the second embodiment, and FIG. 19 is a cross-sectional view taken along the line A-A in FIG. 18. In FIG. 18, the feature of the electrostatic protection element ESD according to the second embodiment resides in that the source region SR extends in the extending direction (y direction) of the gate electrode GE, and in both end portions in the extending direction of the source region SR, a pair of n-type power supply regions NR are disposed.

In FIG. 18, an example in which the pair of n-type power supply regions NR constitute a part of the n-type well NWL is shown, however, the configuration is not limited thereto, and it is also possible to form the pair of n-type power supply regions NR from the n-type semiconductor region having a higher impurity concentration than the n-type well NWL. That is, the feature of the second embodiment resides in that the pair of n-type power supply regions NR are provided in both end portions of the source region SR, and the impurity concentration in the n-type power supply regions NR may be equal to or higher than that in the n-type well NWL.

### Effect of Second Embodiment

In the second embodiment, for example, as shown in FIG. 18, the n-type power supply regions NR are disposed only in both end portions in the y direction of the source region SR. Due to this, according to the electrostatic protection element ESD of the second embodiment, the following effect can be obtained.

For example, when a high voltage due to an electrostatic noise exceeds the avalanche withstand voltage of the pn junction diode formed by the low concentration drain region DR1 and the n-type semiconductor layer NL shown in FIG. 19, avalanche breakdown occurs in the pn junction diode, and a hole and an electron are generated. The generated hole flows from the low concentration drain region DR1 to the drain terminal DE through the medium concentration drain region DR2 and the high concentration drain region DR3. On the other hand, the generated electron flows from the n-type semiconductor layer NL to the source terminal SE through the n-type well NWL and the n-type power supply region NR. At this time, when attention is paid to the flow of the electron, the electron flows from the n-type semiconductor layer NL and passes through the n-type well NWL and the n-type power supply region NR, however, in the second embodiment, the n-type power supply region NR is formed only on both end portions of the source region SR. Due to this, in the second embodiment, the length of the path of the electron flowing from the n-type semiconductor layer NL to the n-type power supply region NR through the n-type well NWL is increased. In consideration that the n-type semiconductor layer NL, the n-type well NWL, and the n-type power supply region NR constitute the base region of the pnp bipolar transistor, this means that the length of the path of the electron flowing in the base region is increased, which means that the base resistance of the pnp bipolar transistor is increased. Therefore, according to the second embodiment, since the base resistance through which the electron flows is increased, a voltage drop is also increased, and thus, a potential difference between the emitter region and the base region of the pnp bipolar transistor is likely to occur. Due to this, according to the electrostatic protection element ESD of the second embodiment, the pnp bipolar transistor is easy to perform an on-operation.

Further, in the second embodiment, since the area of the source region SR serving as the emitter region of the pnp bipolar transistor is increased, when the pnp bipolar transistor performs an on-operation, the injection amount of the carrier (hole) from the emitter region is increased.

Therefore, according to the electrostatic protection element ESD of the second embodiment, a first advantage that the pnp bipolar transistor is easy to perform an on-operation due to an increase in base resistance by providing the n-type power supply region NR only in both end portions of the source region SR, and a second advantage that the current amplification factor can be improved due to an increase in the injection amount of the carrier by increasing the area of the source region SR itself functioning as the emitter region can be obtained. As a result, according to the electrostatic protection element ESD of the second embodiment, by the synergistic effect of the first advantage and the second advantage described above, the on-resistance can be decreased, and thus, the ESD resistance can be improved.

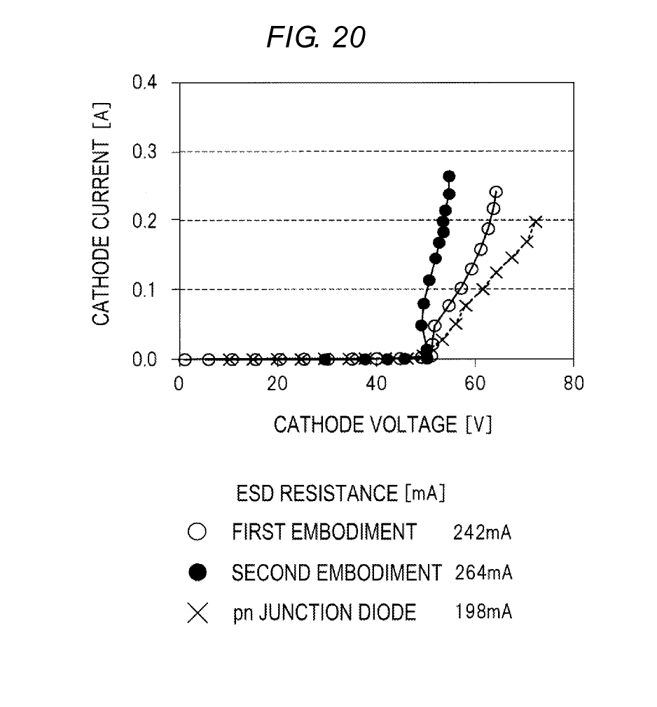

Hereinafter, specific experimental results will be described. FIG. 20 is a graph showing a relationship between a cathode voltage and a cathode current in the electrostatic protection element according to the second embodiment, the electrostatic protection element according to the first embodiment, and for example, an electrostatic protection element constituted only by a diode as the related art 2.

In FIG. 20, the abscissa represents a cathode voltage (V), and the ordinate represents a cathode current (A). The marks correspond to the electrostatic protection element according to the second embodiment, the ∘ marks correspond to the electrostatic protection element according to the first embodiment, and the X marks correspond to the electrostatic protection element constituted only by a pn junction diode.

As shown in FIG. 20, it is found that in the electrostatic protection element according to the second embodiment, the pnp bipolar transistor easily operates, and therefore, a snapback occurs, although the snapback is small, and also the on-resistance is decreased. Therefore, according to the electrostatic protection element of the second embodiment, the ESD resistance corresponding to the breakdown current can be improved as compared with the electrostatic protection element of the first embodiment and the electrostatic protection element constituted only by a pn junction diode.

Specifically, as shown in FIG. 20, the ESD resistance of the electrostatic protection element constituted only by a pn junction diode is 198 mA, and the ESD resistance of the electrostatic protection element according to the first embodiment is 242 mA. On the other hand, it is found that the ESD resistance of the electrostatic protection element according to the second embodiment is 264 mA. From these results, it is found that according to the electrostatic protection element of the second embodiment, the ESD resistance can be improved as compared with the electrostatic protection element constituted only by a pn junction diode and the electrostatic protection element of the first embodiment.

Incidentally, a method for producing a semiconductor device including the electrostatic protection element according to the second embodiment is substantially the same as that of the first embodiment. A different point is that ion implantation of a conductive impurity is performed instead of patterning the source region SR and the n-type power supply region NR. Therefore, also in the second embodiment, basically by undergoing the process shown in FIGS. 11 to 17, a semiconductor device including the electrostatic protection element according to the second embodiment can be produced.

### Third Embodiment

In the third embodiment, an example of a structure in which the high concentration drain region DR3 is not in contact with the field insulating region STI will be described.

### <Structure of Electrostatic Protection Element According to Third Embodiment>

The structure of the electrostatic protection element ESD according to the third embodiment is substantially the same as the structure of the electrostatic protection element ESD according to the first embodiment described above, and therefore, a different point will be mainly described.

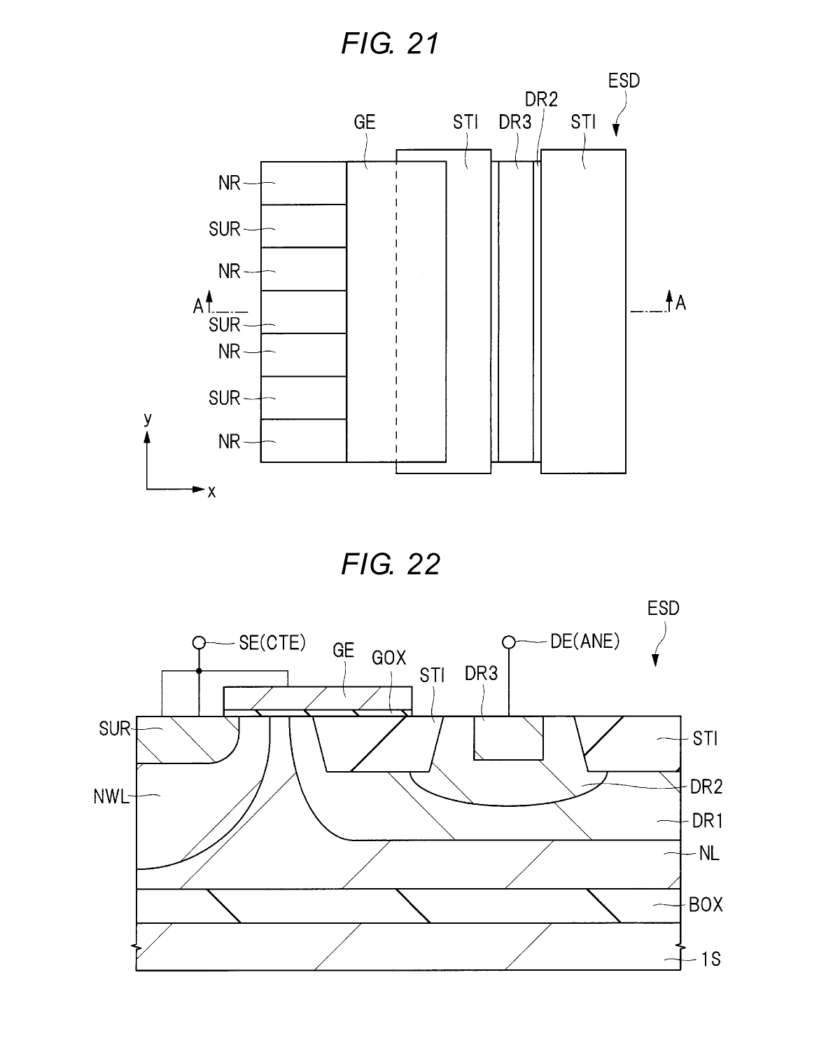

FIG. 21 is a diagram showing a layout structure in plan view of the electrostatic protection element ESD according to the third embodiment, and FIG. 22 is a cross-sectional view taken along the line A-A in FIG. 21. In FIGS. 21 and 22, the feature of the electrostatic protection element ESD according to the third embodiment resides in that the low concentration drain region DR1 and the medium concentration drain region DR2 are in contact with the field insulating region STI, but the high concentration drain region DR3 is not in contact with the field insulating region STI.

### Effect of Third Embodiment

In the third embodiment, for example, as shown in FIGS. 21 and 22, the high concentration drain region DR3 is not in contact with the field insulating region STI. Due to this, according to the electrostatic protection element ESD of the third embodiment, the following effect can be obtained.

For example, a case where a current due to an electrostatic noise flows in the electrostatic protection element ESD is assumed. In this case, if the high concentration drain region DR3 is in contact with the field insulating region STI, an electric field or a current is concentrated in an end portion of the field insulating region STI to cause breakdown of the electrostatic protection element ESD. That is, even if a current flowing in the other region of the electrostatic protection element ESD is equal to or lower than the breakdown current, in a region where an electric field or a current is concentrated such as an end portion of the field insulating region STI, a flowing current is increased. Due to this, even if a current flowing in the electrostatic protection element ESD as a whole is equal to or lower than the breakdown current, in a region where an electric field or a current is concentrated such as an end portion of the field insulating region STI, a large current exceeding the breakdown current flows locally, and due to thermal destruction in this region, the ESD resistance of the electrostatic protection element is limited. That is, when a region where an electric field or a current is concentrated such as an end portion of the field insulating region STI exists, this local region becomes a weak point to decrease the ESD resistance of the electrostatic protection element ESD as a whole.

Therefore, in the third embodiment, as shown in FIGS. 21 and 22, the high concentration drain region DR3 is not in contact with the field insulating region STI. Due to this, according to the third embodiment, the electric field or current concentration in an end portion of the field insulating region STI can be relaxed. Asa result, according to the third embodiment, a large current can be prevented from flowing locally, and thus, the thermal destruction of the electrostatic protection element ESD can be prevented. That is, by configuring the electrostatic protection element ESD according to the third embodiment such that the high concentration drain region DR3 is not in contact with an end portion of the field insulating region STI where an electric field and a current is easily concentrated locally, a weak point where a current easily flows hardly occurs. As a result, according to the electrostatic protection element ESD of the third embodiment, since a configuration in which a weak point hardly occurs is adopted, even if a larger current is made to flow, thermal destruction hardly occurs, and thus, the ESD resistance can be improved.

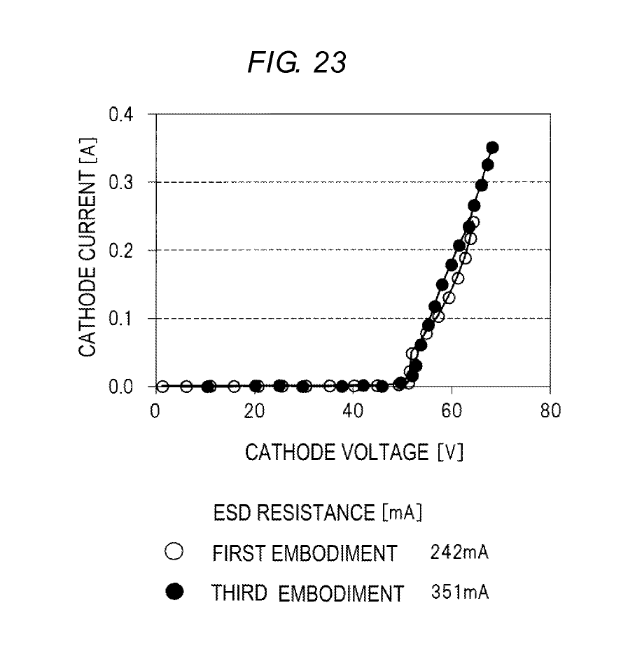

Hereinafter, specific experimental results will be described. FIG. 23 is a graph showing a relationship between a cathode voltage and a cathode current in the electrostatic protection element according to the third embodiment and the electrostatic protection element according to the first embodiment.

In FIG. 23, the abscissa represents a cathode voltage (V), and the ordinate represents a cathode current (A). The marks correspond to the electrostatic protection element according to the third embodiment and the ∘ marks correspond to the electrostatic protection element according to the first embodiment.

As shown in FIG. 23, it is found that the ESD resistance of the electrostatic protection element according to the first embodiment is 242 mA, however, the ESD resistance of the electrostatic protection element according to the third embodiment is 351 mA. From these results, it is found that according to the electrostatic protection element of the third embodiment, the ESD resistance can be improved as compared with the electrostatic protection element of the first embodiment.

### <Method for Producing Semiconductor Device According to Third Embodiment>

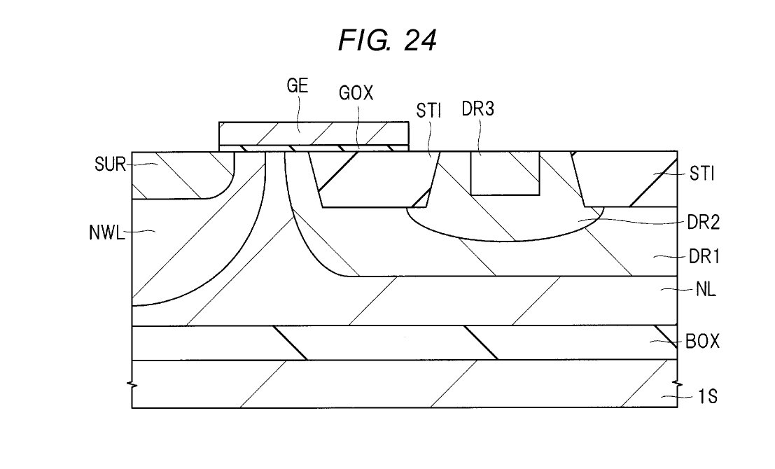

A method for producing a semiconductor device including the electrostatic protection element according to the third embodiment is substantially the same as that of the first embodiment described above. The different point is that the high concentration drain region DR3 is formed apart from the field insulating region STI as shown in FIG. 24. Therefore, also in the third embodiment, basically by undergoing the process shown in FIGS. 11 to 16 and 24, a semiconductor device including the electrostatic protection element according to the third embodiment can be produced.

### Fourth Embodiment

In the fourth embodiment, an example in which the electrostatic protection element ESD according to the second embodiment and the electrostatic protection element ESD according to the third embodiment are combined will be described.

### <Structure of Electrostatic Protection Element According to Fourth Embodiment>

The structure of the electrostatic protection element ESD according to the fourth embodiment is substantially the same as the structure of the electrostatic protection element ESD according to the first embodiment described above, and therefore, a different point will be mainly described.

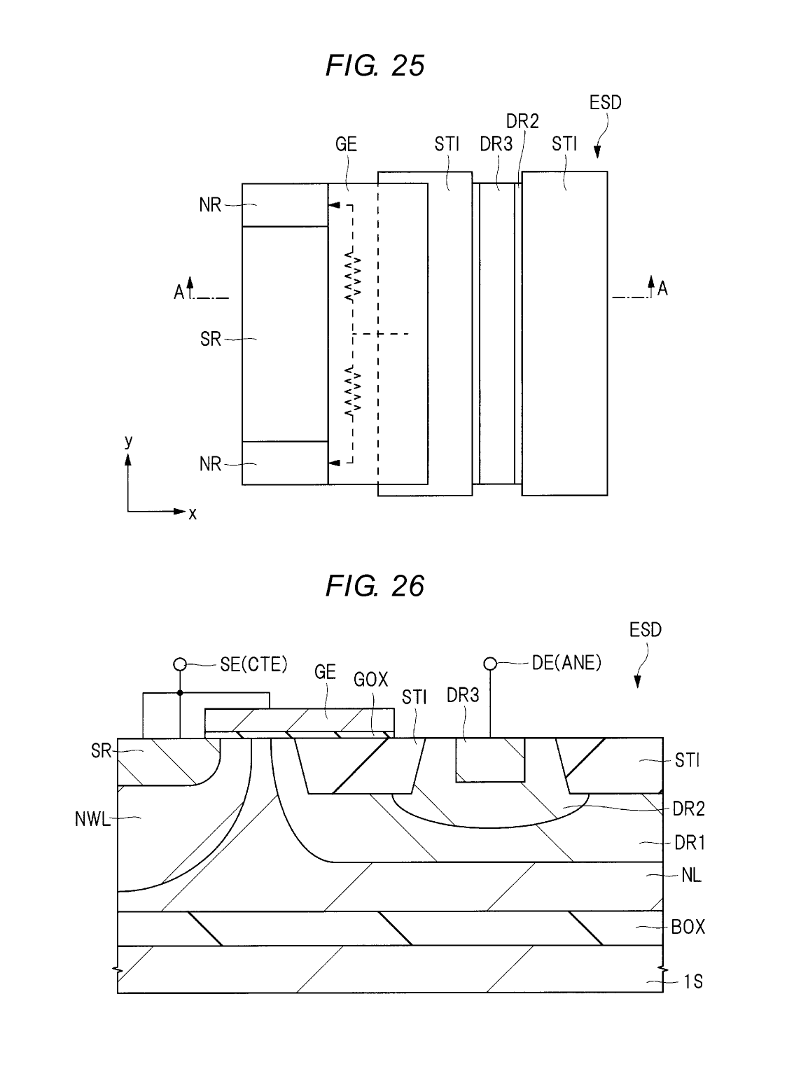

FIG. 25 is a diagram showing a layout structure in plan view of the electrostatic protection element ESD according to the fourth embodiment, and FIG. 26 is a cross-sectional view taken along the line A-A in FIG. 25. In FIGS. 25 and 26, the electrostatic protection element ESD according to the fourth embodiment has two features. A first feature is that the source region SR extends in the extending direction (y direction) of the gate electrode GE, and a pair of n-type power supply regions NR are disposed in both end portions in the extending direction of the source region SR. Further, a second feature is that the low concentration drain region DR1 and the medium concentration drain region DR2 are in contact with the field insulating region STI, but the high concentration drain region DR3 is not in contact with the field insulating region STI. In this manner, the electrostatic protection element ESD according to the fourth embodiment has both of the feature of the second embodiment (first feature) and the feature of the third embodiment (second feature).

### Effect of Fourth Embodiment

The first feature described above is a technical idea for improving the performance of the pnp bipolar transistor parasitically provided for the pn junction diode by modifying the layout structure of the source region SR and the n-type power supply region NR. On the other hand, the second feature described above is a technical idea for suppressing heat generation of the electrostatic protection element ESD by modifying the arrangement of the high concentration drain region DR3. These two technical ideas are not in a trade-off relationship and are independent of each other, and therefore, as the fourth embodiment, by the synergistic effect of a combination of the first feature and the second feature, the ESD resistance of the electrostatic protection element ESD can be further improved.

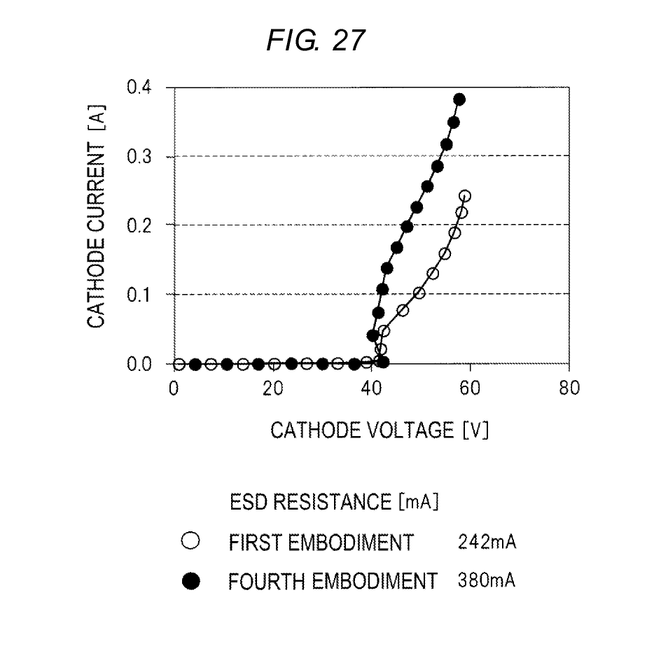

Hereinafter, specific experimental results will be described. FIG. 27 is a graph showing a relationship between a cathode voltage and a cathode current in the electrostatic protection element according to the fourth embodiment and the electrostatic protection element according to the first embodiment.

In FIG. 27, the abscissa represents a cathode voltage (V), and the ordinate represents a cathode current (A). The marks correspond to the electrostatic protection element according to the fourth embodiment and the ∘ marks correspond to the electrostatic protection element according to the first embodiment.

As shown in FIG. 27, it is found that the ESD resistance of the electrostatic protection element according to the first embodiment is 242 mA, however, the ESD resistance of the electrostatic protection element according to the fourth embodiment is 380 mA. From these results, it is found that according to the electrostatic protection element of the fourth embodiment, the ESD resistance can be greatly improved as compared with the electrostatic protection element of the first embodiment.

### <Method for Producing Semiconductor Device According to Fourth Embodiment>

A method for producing a semiconductor device including the electrostatic protection element according to the fourth embodiment is substantially the same as that of the first embodiment described above. The different point is that ion implantation of a conductive impurity is performed instead of patterning the source region SR and the n-type power supply region NR, and also the high concentration drain region DR3 is formed apart from the field insulating region STI as shown in FIG. 24. Therefore, also in the fourth embodiment, basically by undergoing the process shown in FIGS. 11 to 16 and 24, a semiconductor device including the electrostatic protection element according to the fourth embodiment can be produced.

### Fifth Embodiment

In the fifth embodiment, an example in which the electrostatic protection element ESD according to the present invention is applied to, for example, an inverter circuit to be used for controlling a three-phase motor will be described.

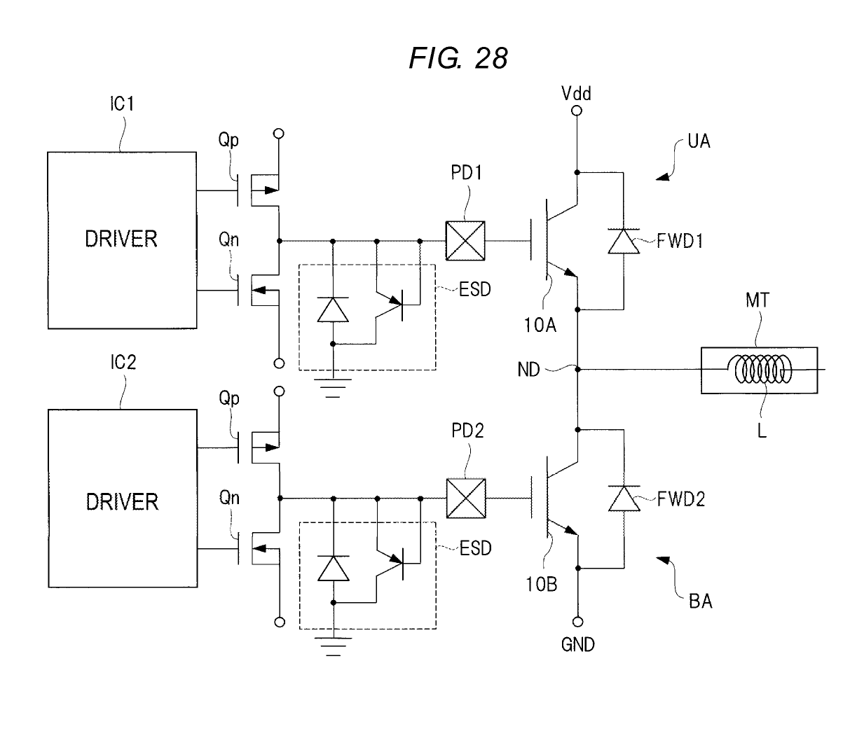

FIG. 28 is a circuit diagram showing a schematic circuit structure of an inverter circuit to be used for controlling a three-phase motor. In FIG. 28, the inverter circuit includes an upper arm UA and a lower arm BA which are connected in series between a power supply potential Vdd and a reference potential (GND potential). The upper arm UA is constituted by an IGBT 10A and a free wheel diode FWD1, and the lower arm BA is constituted by an IGBT 10B and a free wheel diode FWD2. To a connection node ND of the upper arm UA and the lower arm BA, a three-phase motor MT serving as a load is connected. This three-phase motor MT contains an inductance L.

Incidentally, an actual inverter circuit for controlling a three-phase motor MT includes three half bridges composed of an upper arm UA and a lower arm BA described above, however, in FIG. 28, for the sake of simplification, one half bridge is shown.

To a gate electrode of the IGBT 10A constituting the upper arm UA, a pad PD1 is connected, and further the electrostatic protection element ESD of the present invention is connected between the gate electrode of the IGBT 10A and the GND potential. Further, the gate electrode of the IGBT 10A is connected to an intermediate node (output node) of a circuit in which a p-channel field-effect transistor Qp is disposed on a high side, and an n-channel field-effect transistor Qn is disposed on a low side. The gate electrode of the p-channel field-effect transistor Qp and the gate electrode of the n-channel field-effect transistor Qn are electrically connected to a driver IC1.

In the same manner, to a gate electrode of the IGBT 10B constituting the lower arm BA, a pad PD2 is connected, and further the electrostatic protection element ESD of the present invention is connected between the gate electrode of the IGBT 10B and the GND potential. Further, the gate electrode of the IGBT 10B is connected to an intermediate node (output node) of a circuit in which a p-channel field-effect transistor Qp is disposed on a high side, and an n-channel field-effect transistor Qn is disposed on a low side. The gate electrode of the p-channel field-effect transistor Qp and the gate electrode of the n-channel field-effect transistor Qn are electrically connected to a driver IC2.

In the inverter circuit configured in this manner, the on/off of the IGBT 10A is controlled by the on/off control of the p-channel field-effect transistor Qp and the n-channel field-effect transistor Qn by the driver IC1. On the other hand, the on/off of the IGBT 10B is controlled by the on/off control of the p-channel field-effect transistor Qp and the n-channel field-effect transistor Qn by the driver IC2. In particular, in the inverter circuit, when the IGBT 10A constituting the upper arm UA is turned on, control is performed so that the IGBT 10B constituting the lower arm BA is turned off. On the other hand, when the IGBT 10A constituting the upper arm UA is turned off, control is performed so that the IGBT 10B constituting the lower arm BA is turned on. In this manner, a DC power is converted into a three-phase AC power by the inverter circuit, and thus, a three-phase motor MT which is a load containing an inductance can be driven.

Here, in the fifth embodiment, as shown in FIG. 28, since the electrostatic protection element ESD is provided, even if an electrostatic noise is applied to the inverter circuit, the circuit elements such as the IGBT 10A, the IGBT 10B, the p-channel field-effect transistor Qp, the n-channel field-effect transistor Qn, the driver IC1, and the driver IC2 can be protected from the electrostatic noise. In particular, according to the electrostatic protection element ESD of the present invention, the breakdown current (ESD resistance) can be further improved while maintaining the usefulness that the electrostatic protection element can be used in a circuit containing an inductance without any problems, and thus, an advantage that the electrostatic protection element ESD having high performance can be provided for the inverter circuit described in the fifth embodiment is obtained.

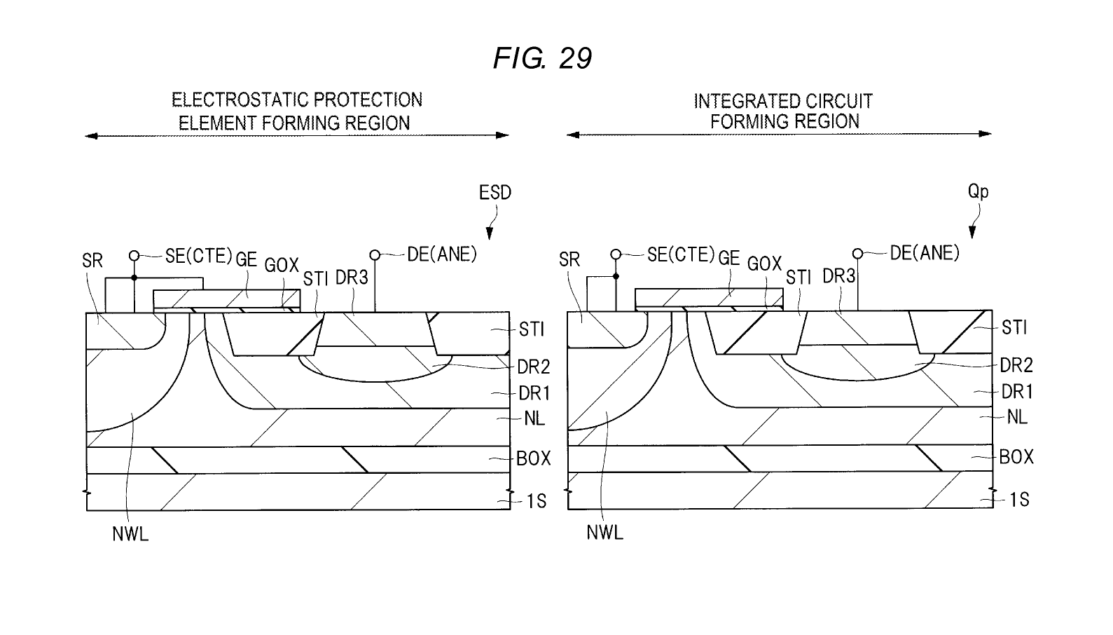

Further, the electrostatic protection element ESD of the present invention has the same structure as that of the p-channel field-effect transistor Qp shown in FIG. 28, and has an advantage that it can be formed together on a semiconductor substrate on which the p-channel field-effect transistor Qp is formed. Specifically, FIG. 29 is a cross-sectional view showing a structure in which the p-channel field-effect transistor Qp is formed in an integrated circuit forming region of a semiconductor substrate and the electrostatic protection element ESD is formed in an electrostatic protection element forming region of the same semiconductor substrate.

In FIG. 29, in the semiconductor device according to the fifth embodiment, along with the electrostatic protection element ESD, the p-channel field-effect transistor Qp included in an integrated circuit having a different function from that of the electrostatic protection element ESD is also formed. At this time, as shown in FIG. 28, the integrated circuit described above is a circuit for controlling a load containing an inductance. The p-channel field-effect transistor Qp included in this integrated circuit constitutes, as shown in FIG. 29, a semiconductor element which has the same structure as that of the electrostatic protection element ESD, and has a different function from that of the electrostatic protection element ESD because of having a structure in which the source region SR and the gate electrode GE are not electrically connected to each other. That is, as shown in FIG. 29, the electrostatic protection element ESD and the p-channel field-effect transistor Qp have the same semiconductor element structure. However, in the electrostatic protection element ESD, the source region SR, the n-type well NWL, and the gate electrode GE are electrically connected to one another, and therefore, the electrostatic protection element ESD functions as a pn junction diode in which a pnp bipolar transistor is parasitically formed. On the other hand, in the p-channel field-effect transistor Qp, the source region SR and the gate electrode GE are not electrically connected to each other, and therefore, the p-channel field-effect transistor Qp functions as a common switching element in which the source terminal SE and the gate electrode GE are not electrically connected to each other.

As described above, the electrostatic protection element ESD according to the present invention can be formed to have the same structure as that of the p-channel field-effect transistor Qp included in the integrated circuit, and therefore, an advantage that while utilizing a production process for forming a p-channel field-effect transistor on a semiconductor substrate as such, the electrostatic protection element ESD can be formed on the same semiconductor substrate can be obtained. Asa result, without adding a process for producing the electrostatic protection element ESD independently, in other words, without complicating the production process, the semiconductor device including the integrated circuit and the electrostatic protection element ESD can be produced.

Hereinabove, the present invention accomplished by the present inventors has been specifically described with reference to the embodiments, however, it goes without saying that the present invention is not limited to the embodiments described above, and can be modified variously within a range that does not depart from the gist of the present invention.

What is claimed is:

1. A semiconductor device, comprising an electrostatic protection element including:
(a) a source region which has a p-type semiconductor region formed on an n-type semiconductor layer;
(b) a drain region which has a p-type semiconductor region formed apart from the source region on the n-type semiconductor layer;
(c) an n-type semiconductor region which is formed on the n-type semiconductor layer and is in contact with the source region;
(d) a gate insulating film which is formed on the n-type semiconductor layer; and
(e) a gate electrode which is formed on the gate insulating film, wherein
the source region, the n-type semiconductor region, and the gate electrode are electrically connected to one another.

2. The semiconductor device according to claim 1, wherein
the electrostatic protection element includes:
(f1) a pn junction diode, which is formed by the n-type semiconductor layer and the drain region, and in which the source region electrically connected to the n-type semiconductor layer through the n-type semiconductor region is used as a cathode region, and the drain region is used as an anode region; and
(f2) a pnp bipolar transistor, in which the source region is used as an emitter region, the n-type semiconductor region and the n-type semiconductor layer are used as a base region, and the drain region is used as a collector region.

3. The semiconductor device according to claim 2, wherein
the electrostatic protection element functions as a semiconductor element in which the pnp bipolar transistor and the pn junction diode are combined.

4. The semiconductor device according to claim 1, wherein
the source region is constituted by multiple source unit regions,
the multiple source unit regions are arranged at a predetermined interval in the direction in which the gate electrode extends,
an n-type power supply region is disposed in each of the multiple spaces with a predetermined interval, and
the n-type power supply region is electrically connected to the n-type semiconductor region.

5. The semiconductor device according to claim 4, wherein
the impurity concentration in the n-type power supply region is higher than the impurity concentration in the n-type semiconductor region.

6. The semiconductor device according to claim 4, wherein
the n-type power supply region constitutes a part of the n-type semiconductor region.

7. The semiconductor device according to claim 1, wherein
the source region extends in the extending direction of the gate electrode,
a pair of n-type power supply regions are disposed in both end portions in the extending direction of the source region, and
the pair of n-type power supply regions are electrically connected to the n-type semiconductor region.

8. The semiconductor device according to claim 7, wherein
the pair of n-type power supply regions constitute a part of the n-type semiconductor region.

9. The semiconductor device according to claim 1, wherein
a field insulating region is formed on the n-type semiconductor layer between the source region and the drain region.

10. The semiconductor device according to claim 9, wherein
the drain region includes:
(g1) an impurity region which has a first impurity concentration; and
(g2) a high concentration impurity region, which has a higher impurity concentration than the impurity region and is included in the impurity region.

11. The semiconductor device according to claim 10, wherein
the impurity region is in contact with the field insulating region, and the high concentration impurity region is not in contact with the field insulating region.

12. The semiconductor device according to claim 1, wherein
the source region extends in the extending direction of the gate electrode,
a pair of n-type power supply regions, which constitute apart of the n-type semiconductor region, are disposed in both end portions in the extending direction of the source region,
a field insulating region is formed on the n-type semiconductor layer between the source region and the drain region,
the drain region includes an impurity region which has a first impurity concentration, and a high concentration impurity region, which has a higher impurity concentration than the impurity region and is included in the impurity region, and
the impurity region is in contact with the field insulating region, and the high concentration impurity region is not in contact with the field insulating region.

13. The semiconductor device according to claim 1, wherein
in the semiconductor device, along with the electrostatic protection element, an integrated circuit having a different function from that of the electrostatic protection element is also formed.

14. The semiconductor device according to claim 13, wherein
the integrated circuit includes a semiconductor element, which has the same structure as that of the electrostatic protection element, but is configured such that the source region and the gate electrode are not electrically connected to each other, and therefore has a different function from that of the electrostatic protection element.

15. The semiconductor device according to claim 13, wherein
the integrated circuit includes a circuit for controlling a load containing an inductance.
